(19) United States
(12) Patent Application Publication
(10) Pub. No.: US 2012/0154325 A1
(43) Pub. Date: Jun. 21, 2012

(54) TOUCHSCREEN PANEL

(75) Inventor: Yutaka Ueno, Tokyo (JP)

(73) Assignee: FUJITSU COMPONENT LIMITED, Tokyo (JP)

(21) Appl. No.: 13/309,666

(22) Filed: Dec. 2, 2011

(30) Foreign Application Priority Data
Dec. 15, 2010 (JP) 2010-279713

(51) Int. Cl. G06F 3/045; G01R 27/08

(52) U.S. Cl. 345/174; 324/714

(57) ABSTRACT

A touchscreen panel includes an upper resistive film including a first upper electrode and a second upper electrode provided at a first end and a second end, respectively, in a first direction; a lower resistive film including a first lower electrode and a second lower electrode provided at a first end and a second end, respectively, in a second direction perpendicular to the first direction; a first electric potential detecting part connected to the first upper electrode; a second electric potential detecting part connected to the second upper electrode; a third electric potential detecting part connected to the first lower electrode; and a fourth electric potential detecting part connected to the second lower electrode.

### CROSS-REFERENCE TO RELATED APPLICATION

The present application is based upon and claims the benefit of priority of Japanese Patent Application No. 2010-279713, filed on Dec. 15, 2010, the entire contents of which are incorporated herein by reference.

### BACKGROUND OF THE INVENTION

1. Field of the Invention

The present invention relates to a touchscreen panel.

2. Description of the Related Art

Many touchscreen panels that are widely used nowadays include a touchscreen panel. The touchscreen panel allows information to be input to electronic apparatuses through a direct contact of a finger or the like with the touchscreen panel. The touchscreen panel is expected to be more popular in the future as a simple device for inputting information.

Most of the common touchscreen panels are configured to detect a position of contact when the contact is made at one point. Accordingly, if there are two or more points of contact on the touchscreen panel, it is not possible to detect the position information of the contact points with accuracy. Accordingly, there is a demand for a method that makes it possible to detect position information at each contact point with accuracy in the case of two or more contact points as well.

For example, Japanese Laid-Open Patent Application No. 5-181591 and Japanese Laid-Open Patent Application No. 6-149463 disclose methods where electrodes in an upper resistive film and electrodes in a lower resistive film are divided to detect a position in the case of two or more contact points as well.

### SUMMARY OF THE INVENTION

According to an aspect of the present invention, a touchscreen panel includes an upper resistive film including a first upper electrode and a second upper electrode provided at a first end and a second end, respectively, in a first direction; a lower resistive film including a first lower electrode and a second lower electrode provided at a first end and a second end, respectively, in a second direction perpendicular to the first direction; a first electric potential detecting part connected to the first upper electrode; a second electric potential detecting part connected to the second upper electrode; a third electric potential detecting part connected to the first lower electrode; and a fourth electric potential detecting part connected to the second lower electrode.

According to an aspect of the present invention, a touchscreen panel includes an upper resistive film including a first upper electrode and a second upper electrode provided at a first end and a second end, respectively, in a first direction, the first upper electrode and the second upper electrode each being divided into a plurality of portions; a lower resistive film including a first lower electrode and a second lower electrode provided at a first end and a second end, respectively, in a second direction perpendicular to the first direction, the first lower electrode and the second lower electrode each being divided into a plurality of portions; a plurality of first electric potential detecting parts connected to the portions of the first upper electrode on a one-to-one basis; a plurality of second electric potential detecting parts connected to the portions of the second upper electrode on a one-to-one basis; a plurality of third electric potential detecting parts connected to the portions of the first lower electrode on a one-to-one basis; and a plurality of fourth electric potential detecting parts connected to the portions of the second lower electrode on a one-to-one basis.

The object and advantages of the embodiments will be realized and attained by means of the elements and combinations particularly pointed out in the claims.

It is to be understood that both the foregoing general description and the following detailed description are exemplary and explanatory and not restrictive of the invention as claimed.

### BRIEF DESCRIPTION OF THE DRAWINGS

Other objects, features and advantages of the present invention will become more apparent from the following detailed description when read in conjunction with the accompanying drawings, in which:

FIG. 1 is a diagram illustrating a configuration of a touchscreen panel according to a first embodiment;

FIG. 2 is a diagram illustrating position detection in the touchscreen panel according to the first embodiment;

FIG. 3 is another diagram illustrating the position detection in the touchscreen panel according to the first embodiment;

FIG. 4 is a flowchart illustrating a position detecting method of the touchscreen panel according to the first embodiment;

FIG. 5 is another diagram illustrating the position detection in the touchscreen panel according to the first embodiment;

FIG. 6 is another diagram illustrating the position detection in the touchscreen panel according to the first embodiment;

FIG. 7 is another diagram illustrating the position detection in the touchscreen panel according to the first embodiment;

FIG. 8 is another diagram illustrating the position detection in the touchscreen panel according to the first embodiment;

FIG. 9 is another diagram illustrating the position detection in the touchscreen panel according to the first embodiment;

FIG. 10 is another diagram illustrating the position detection in the touchscreen panel according to the first embodiment;

FIG. 11 is another diagram illustrating the position detection in the touchscreen panel according to the first embodiment;

FIG. 12 is another diagram illustrating the position detection in the touchscreen panel according to the first embodiment;

FIG. 13 is a diagram illustrating a configuration of a touchscreen panel according to a second embodiment;

FIG. 14 is a diagram illustrating position detection in the touchscreen panel according to the second embodiment;

FIG. 15 is another diagram illustrating the position detection in the touchscreen panel according to the second embodiment;

FIG. 16 is a flowchart illustrating a position detecting method of the touchscreen panel according to the second embodiment;

FIG. 17 is another diagram illustrating the position detection in the touchscreen panel according to the second embodiment;

FIG. 18 is another diagram illustrating the position detection in the touchscreen panel according to the second embodiment; and

FIG. 19 is another diagram illustrating the position detection in the touchscreen panel according to the second embodiment.

### DETAILED DESCRIPTION OF THE PREFERRED EMBODIMENTS

As described above, Japanese Laid-Open Patent Application No. 5-181591 and Japanese Laid-Open Patent Application No. 6-149463 disclose methods of detecting a position in the case of two or more contact points as well. However, these methods have the problem of complicated control. Further, regarding two contact points on the touchscreen panel, position detection may not go so far as to require the capability of detecting position coordinates with accuracy at each contact point, and if some information is obtained on a direction of movement and positions in the case of moving the contact points, an operation may be performed based on the information.

Therefore, there is a demand for touchscreen panels capable of detecting the position information of two contact points with as simple a structure and control as possible.

According to an aspect of the present invention, a touchscreen panel is provided that is configured to detect the position information of two contact points with as simple a structure and control as possible.

According to an aspect of the present invention, a four-wire touchscreen panel is provided that is configured to detect the position information of two contact points with as simple a structure and control as possible.

A description is given below, with reference to the accompanying drawings, of embodiments of the present invention.

### [a] First Embodiment

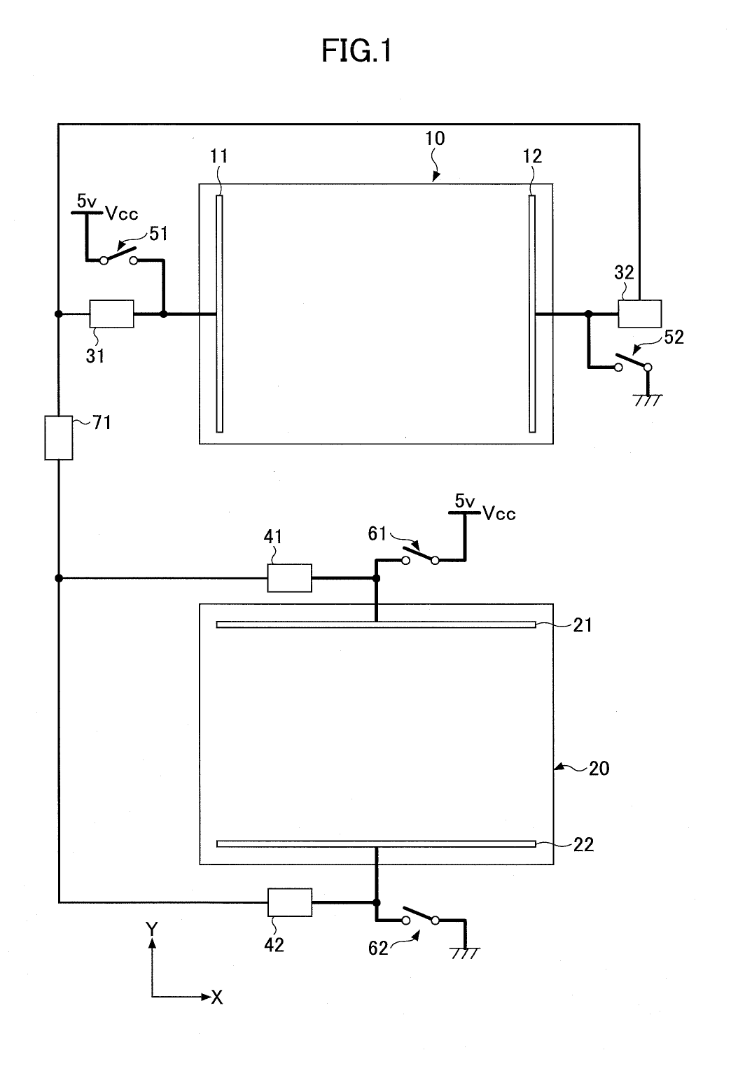

A description is given, with reference to FIG. 1, of a touchscreen panel according to a first embodiment of the present invention.

### [Structure of Touchscreen Panel]

First, a description is given of a structure of the touchscreen panel according to this embodiment.

The touchscreen panel according to this embodiment includes an upper resistive film 10 and a lower resistive film 20. Each of the upper resistive film 10 and the lower resistive film 20 is formed of a transparent electrically conductive film of ITO (indium tin oxide) or the like, and has a substantially square or substantially rectangular shape. Each of the upper resistive film 10 and the lower resistive film 20 may be formed on the surface of a glass substrate, a transparent film or the like. For example, if the upper resistive film 10 is formed on a transparent film and the lower resistive film 20 is formed on a glass substrate, the upper resistive film 10 and the lower resistive film 20 are so arranged as to face each other.

A first upper electrode 11 and a second upper electrode 12 are formed along the Y-axis directions at a first end and a second end, respectively, in the X-axis directions on the upper resistive film 10. Further, a first lower electrode 21 and a second lower electrode 22 are formed along the X-axis directions at a first end and a second end, respectively, in the Y-axis directions on the lower resistive film 20.

The first upper electrode 11 is connected to a first electric potential detecting part 31 configured to detect an electric potential at the first upper electrode 11. The first upper electrode 11 is also connected to a power supply potential (supply voltage) Vcc via a switch 51. According to this embodiment, the power supply potential Vcc is 5 V. The power supply potential Vcc is referred to as “first electric potential.”

The second upper electrode 12 is connected to a second electric potential detecting part 32 configured to detect an electric potential at the second upper electrode 12. The second upper electrode 12 is grounded via a switch 52. According to this embodiment, the ground potential is 0 V. The ground potential is referred to as “second electric potential.”

The first lower electrode 21 is connected to a third electric potential detecting part 41 configured to detect an electric potential at the first lower electrode 21. The first lower electrode 21 is also connected to the power supply potential Vcc via a switch 61.

The second lower electrode 22 is connected to a fourth electric potential detecting part 42 configured to detect an electric potential at the second lower electrode 22. The second lower electrode 22 is grounded via a switch 62.

The first electric potential detecting part 31, the second electric potential detecting part 32, the third electric potential detecting part 41, and the fourth electric potential detecting part 42 are connected to a control part 71. The control part 71 performs control based on the electric potentials detected in the first electric potential detecting part 31, the second electric potential detecting part 32, the third electric potential detecting part 41, and the fourth electric potential detecting part 42. Further, the control part 71 also performs ON-OFF control of the switches 51, 52, 61, and 62 via interconnects (not graphically illustrated).

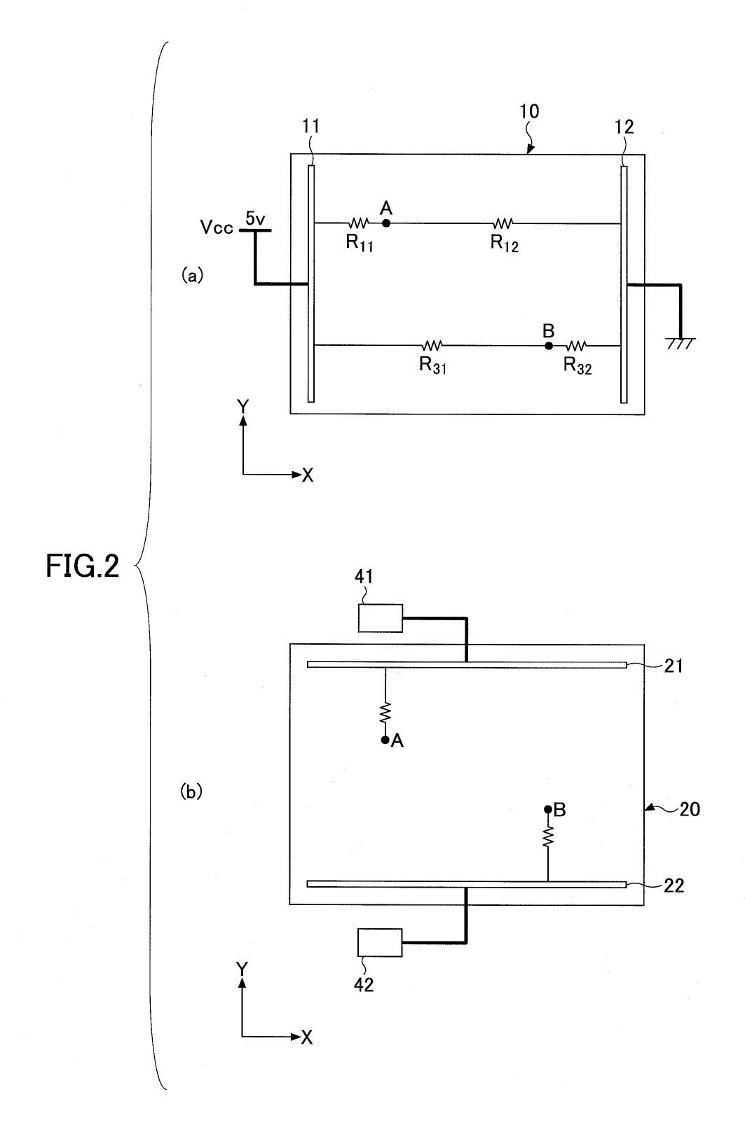

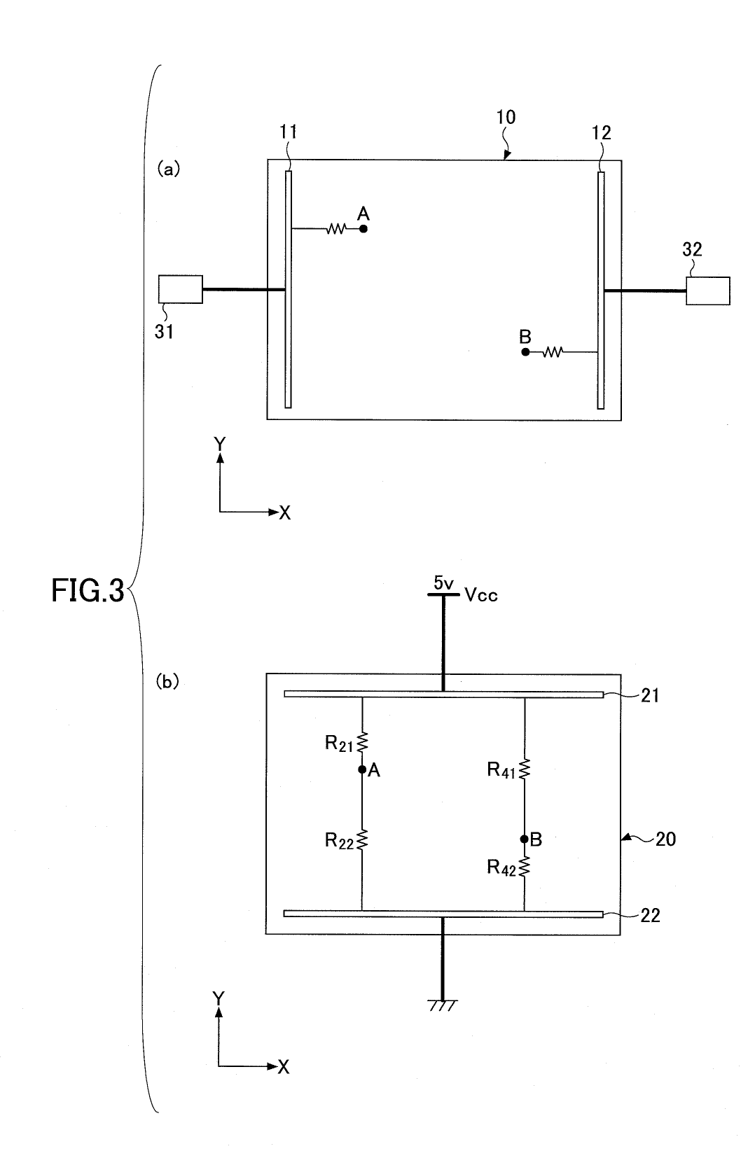

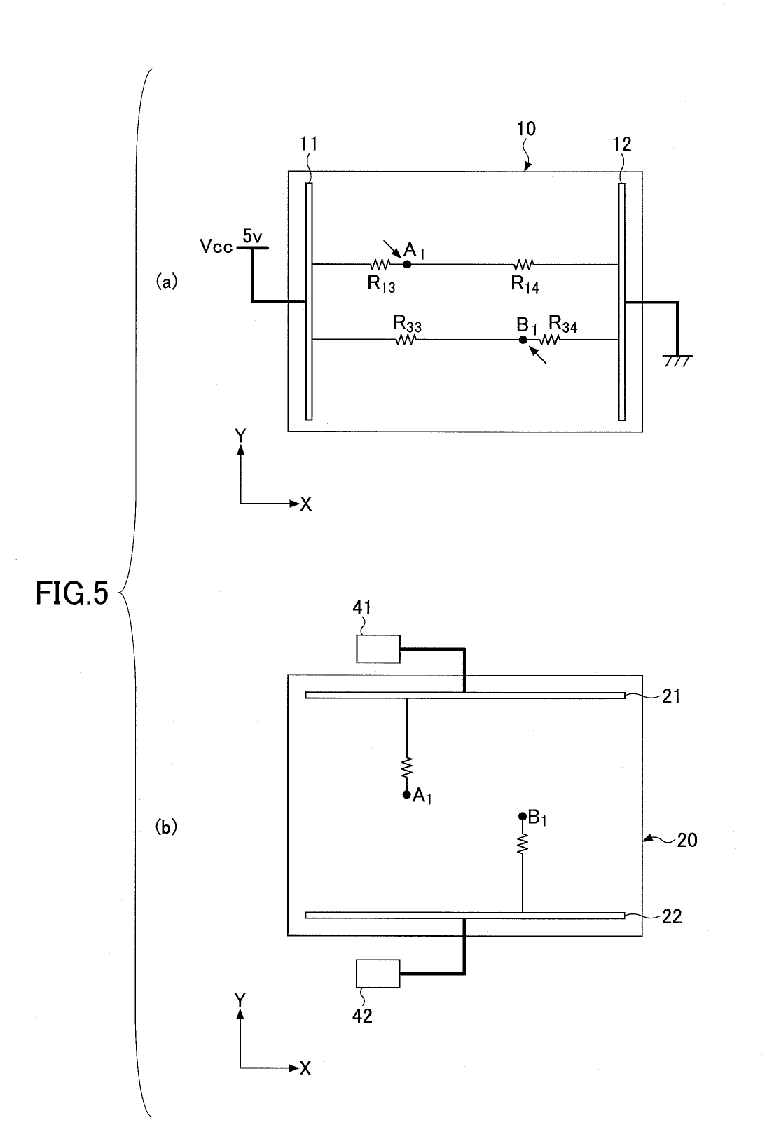

In FIG. 1, the upper resistive film 10 and the lower resistive film 20 are illustrated as being separated for convenience of description. According to the touchscreen panel of this embodiment, however, the upper resistive film 10 is provided on the lower resistive film 20. The same applies to the subsequent drawings. Further, in FIG. 2, FIG. 3, and FIG. 5 through FIG. 12, (a) illustrates the upper resistive film 10 and (b) illustrates the lower resistive film 20.

### [Position Detection in X-axis Directions]

In the touchscreen panel according to this embodiment, first, an electric potential distribution is formed in the upper resistive film 10, and electric potentials are measured via the lower resistive film 20.

For example, in the touchscreen panel having the structure illustrated in FIG. 1, the switches 51 and 52 are turned ON and the switches 61 and 62 are turned OFF. As a result, as illustrated in FIG. 2, a voltage of 5 V is applied to the first upper electrode 11, and the second upper electrode 12 is grounded, so that an electric potential distribution having a gradient in an X-axis direction is generated in the upper resistive film 10.

In this state, for example, it is assumed that contact is made at two Points A and B on the touchscreen panel. In this case, the electric potential at Point A is a value obtained by dividing a voltage between a resistance component R₁₁ and a resistance component R₁₂, that is, 5×R₁₂/(R₁₁+R₁₂) V. Further, the electric potential at Point B is a value obtained by dividing a voltage between a resistance component R₃₁ and a resistance component R₃₂, that is, 5×R₃₂/(R₃₁+R₃₂) V.

These electric potentials are detected via the lower resistive film 20, and in general, an electric potential at the midpoint between Point A and Point B is supposed to be detected. However, since the lower resistive film 20 has a resistance component, the potentials at Point A and Point B strongly affect the closer of the first lower electrode 21 and the second lower electrode 22.

That is, in the case where the first lower electrode 21 is closer than the second lower electrode 22 at Point A and the second lower electrode 22 is closer than the first lower electrode 21 at Point B as illustrated in FIG. 2, the effect of Point A is dominant in the electric potential detected at the first lower electrode 21, and the effect of Point B is dominant in the electric potential detected at the second lower electrode 22.

In other words, comparing the resistance component between Point A and the first lower electrode 21 and the resistance component between Point B and the first lower electrode 21, the resistance value is lower in the resistance component between Point A and the first lower electrode 21. Accordingly, the first lower electrode 21 is strongly affected by the electric potential at Point A. Comparing the resistance component between Point A and the second lower electrode 22 and the resistance component between Point B and the second lower electrode 22, the resistance value is lower in the resistance component between Point B and the second lower electrode 22. Accordingly, the second lower electrode 22 is strongly affected by the electric potential at Point B.

Thus, different values are detected for the electric potential detected in the third electric potential detecting part 41 via the first lower electrode 21 and the electric potential detected in the fourth electric potential detecting part 42 via the second lower electrode 22.

On the other hand, if contact is made at a single point with voltage applied in the same manner, the electric potential detected in the third electric potential detecting part 41 and the electric potential detected in the fourth electric potential detecting part 42 are equal. Accordingly, a determination as to whether the electric potential detected in the third electric potential detecting part 41 and the electric potential detected in the fourth electric potential detecting part 42 are equal may be used to determine whether the number of contact points is one or two.

Further, as described above, the electric potential at Point A is a value obtained by dividing a voltage between the resistance component Ru and the resistance component R₁₂, and the electric potential at Point B is a value obtained by dividing a voltage between the resistance component R₃₁ and the resistance component R₃₂. Therefore, it is also possible to detect x coordinate positions at Point A and Point B based on the electric potential detected in the third electric potential detecting part 41 and the electric potential detected in the fourth electric potential detecting part 42.

For example, the correlation between the x coordinate positions at two contact points and the electric potentials detected in the third electric potential detecting part 41 and the fourth electric potential detecting part 42 may be studied in advance, and the x coordinate positions at Point A and Point B may be detected (determined) from the electric potential detected in the third electric potential detecting part 41 or the fourth electric potential detecting part 42 based on the correlation.

### [Position Detection in Y-axis Directions]

Next, an electric potential distribution is formed in the lower resistive film 20, and electric potentials are measured via the upper resistive film 10.

For example, in the touchscreen panel having the structure illustrated in FIG. 1, the switches 51 and 52 are turned OFF and the switches 61 and 62 are turned ON. As a result, as illustrated in FIG. 3, a voltage of 5 V is applied to the first lower electrode 21, and the second lower electrode 22 is grounded, so that an electric potential distribution having a gradient in a Y-axis direction is generated in the lower resistive film 20.

In this state, for example, it is assumed that contact is made at two points A and B on the touchscreen panel. In this case, the electric potential at Point A is a value obtained by dividing a voltage between a resistance component R₂₁ and a resistance component R₂₂, that is, 5×R₂₂/(R₂₁+R₂₂) V. Further, the electric potential at Point B is a value obtained by dividing a voltage between a resistance component R₄₁ and a resistance component R₄₂, that is, 5×R₄₂/(R₄₁+R₄₂) V.

These electric potentials are detected via the upper resistive film 10, and in general, an electric potential at the midpoint between Point A and Point B is supposed to be detected. However, since the upper resistive film 10 has a resistance component, the potentials at Point A and Point B strongly affect the closer of the first upper electrode 11 and the second upper electrode 12.

That is, in the case where the first upper electrode 11 is closer than the second upper electrode 12 at Point A and the second upper electrode 12 is closer than the first upper electrode 11 at Point B as illustrated in FIG. 3, the effect of Point A is dominant in the electric potential detected at the first upper electrode 11, and the effect of Point B is dominant in the electric potential detected at the second upper electrode 12.

In other words, comparing the resistance component between Point A and the first upper electrode 11 and the resistance component between Point B and the first upper electrode 11, the resistance value is lower in the resistance component between Point A and the first upper electrode 11. Accordingly, the first upper electrode 11 is strongly affected by the electric potential at Point A. Comparing the resistance component between Point A and the second upper electrode 12 and the resistance component between Point B and the second upper electrode 12, the resistance value is lower in the resistance component between Point B and the second upper electrode 12. Accordingly, the second upper electrode 12 is strongly affected by the electric potential at Point B.

Thus, different values are detected for the electric potential detected in the first electric potential detecting part 31 via the first upper electrode 11 and the electric potential detected in the second electric potential detecting part 32 via the second upper electrode 12.

On the other hand, if contact is made at a single point with voltage applied in the same manner, the electric potential detected in the first electric potential detecting part 31 and the electric potential detected in the second electric potential detecting part 32 are equal. Accordingly, a determination as to whether the electric potential detected in the first electric potential detecting part 31 and the electric potential detected in the second electric potential detecting part 32 are equal may be used to determine whether the number of contact points is one or two.

Further, as described above, the electric potential at Point A is a value obtained by dividing a voltage between the resistance component R₂₁ and the resistance component R₂₂, and the electric potential at Point B is a value obtained by dividing a voltage between the resistance component R₄₁ and the resistance component R₄₂. Therefore, it is also possible to detect y coordinate positions at Point A and Point B based on the electric potential detected in the first electric potential detecting part 31 and the electric potential detected in the second electric potential detecting part 32.

For example, the correlation between the y coordinate positions at two contact points and the electric potentials detected in the first electric potential detecting part 31 and the second electric potential detecting part 32 may be studied in advance, and the y coordinate positions at Point A and Point B may be detected (determined) from the electric potential detected in the first electric potential detecting part 31 or the second electric potential detecting part 32 based on the correlation.

### [Position Detecting Method of Touchscreen Panel]

Next, a description is given of a position detecting method of the touchscreen panel according to this embodiment.

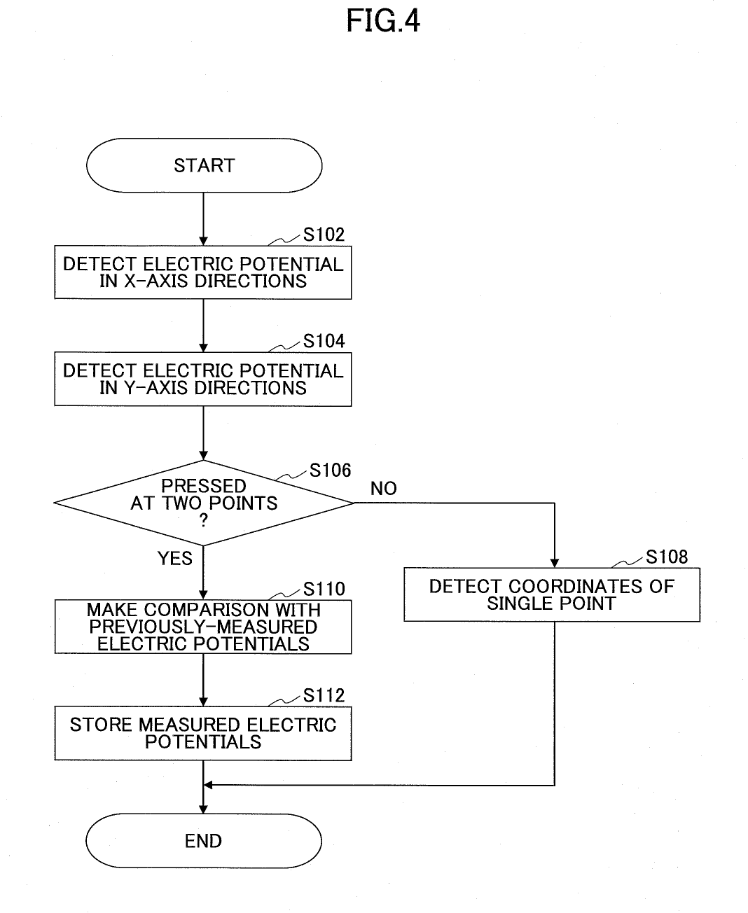

FIG. 4 is a flowchart illustrating a position detecting method of the touchscreen panel according to this embodiment.

First, in step S102, an electric potential in the X-axis directions is detected. For example, in the touchscreen panel having the structure illustrated in FIG. 1, the switches 51 and 52 are turned ON and the switches 61 and 62 are turned OFF, so that the touchscreen panel is in the state illustrated in FIG. 2. In this state, an electric potential is measured by the third electric potential detecting part 41 via the first lower electrode 21 formed on the lower resistive film 20, and an electric potential is measured by the fourth electric potential detecting part 42 via the second lower electrode 22 formed on the lower resistive film 20.

Next, in step S104, an electric potential in the Y-axis directions is detected. For example, in the touchscreen panel having the structure illustrated in FIG. 1, the switches 51 and 52 are turned OFF and the switches 61 and 62 are turned ON, so that the touchscreen panel is in the state illustrated in FIG. 3. In this state, an electric potential is measured by the first electric potential detecting part 31 via the first upper electrode 11 formed on the upper resistive film 10, and an electric potential is measured by the second electric potential detecting part 32 via the second upper electrode 12 formed on the upper resistive film 10.

Next, in step S106, it is determined whether the number of contact points on the touchscreen panel is one or two (whether the touchscreen panel is contacted at one point or two points). For example, this determination is performed by determining whether the electric potential detected by the third electric potential detecting part 41 and the electric potential detected by the fourth electric potential detecting part 42 in step S102 are equal and the electric potential detected by the first electric potential detecting part 31 and the electric potential detected by the second electric potential detecting part 32 in step S104 are equal.

That is, if the electric potential detected by the third electric potential detecting part 41 and the electric potential detected by the fourth electric potential detecting part 42 in step S102 are equal and the electric potential detected by the first electric potential detecting part 31 and the electric potential detected by the second electric potential detecting part 32 in step S104 are equal, it is determined that the number of contact points on the touchscreen panel is one (NO in step S106), and the process proceeds to step S108.

In other cases, that is, if at least the electric potential detected by the third electric potential detecting part 41 and the electric potential detected by the fourth electric potential detecting part 42 are different or the electric potential detected by the first electric potential detecting part 31 and the electric potential detected by the second electric potential detecting part 32 are different, it is determined that the number of contact points on the touchscreen panel is two (YES in step S106), and the process proceeds to step S110.

Next, in step S108, since it is determined that the number of contact points on the touchscreen panel is one, the coordinate position at the contact point on the touchscreen panel is detected by the same method as is employed in common four-wire touchscreen panels. Information on the detected coordinate position and the electric potentials detected in step S102 and step S104 are stored as required in a storage part (not graphically illustrated) provided in the control part 71 (FIG. 1) or the like.

On the other hand, in step S110, since it is determined that the number of contact points on the touchscreen panel is two, the electric potentials detected in step S102 and step S104 at a present time (in the current process) are compared with the electric potentials detected in step S102 and step S104 at a previous time (in the previous process), which may be stored in the storage part of the control part 71. That is, the electric potentials detected in the third electric potential detecting part 41 and the fourth electric potential detecting part 42 at the present time are compared with the electric potentials detected in the third electric potential detecting part 41 and the fourth electric potential detecting part 42 at the previous time, and the electric potentials detected in the first electric potential detecting part 31 and the second electric potential detecting part 32 at the present time are compared with the electric potentials detected in the first electric potential detecting part 31 and the second electric potential detecting part 32 at the previous time.

A description is given in detail below of this comparison process. Comparing these electric potentials makes it possible to detect, for example, the direction of movement of the two contact points. Based on information on the direction of movement of the two contact points thus detected, it is possible to control a display screen or the like which the touchscreen panel of this embodiment is provided in or mounted on. For example, it is possible to determine whether the two contact points are approaching or moving away from each other, or to determine whether the two contact points are to rotate. Based on this information, it is possible to enlarge, reduce, or rotate an image displayed on the display screen.

Likewise, in the case where the number of contact points detected at the previous time is one as well, it is possible to detect the direction of movement of the contact point by comparing the electric potentials detected in the third electric potential detecting part 41 and the fourth electric potential detecting part 42 at the present time with the electric potentials detected in the third electric potential detecting part 41 and the fourth electric potential detecting part 42 at the previous time, and comparing the electric potentials detected in the first electric potential detecting part 31 and the second electric potential detecting part 32 at the present time with the electric potentials detected in the first electric potential detecting part 31 and the second electric potential detecting part 32 at the previous time. If there is no electric potential measured at the previous time, this step (step S110) is omitted, and the process proceeds to step S112.

In addition, the x coordinate positions of the two contact points on the touchscreen panel may be detected based on the electric potentials detected in step S102 at the present time, that is, the electric potentials detected in the third electric potential detecting part 41 and the fourth electric potential detecting part 42 at the present time, and the y coordinate positions of the two contact points on the touchscreen panel may be detected based on the electric potentials detected in step S104 at the present time, that is, the electric potentials detected in the first electric potential detecting part 31 and the second electric potential detecting part 32 at the present time.

Next, in step S112, the electric potentials detected at the present time in the third electric potential detecting part 41, the fourth electric potential detecting part 42, the first electric potential detecting part 31, and the second electric potential detecting part 32 are stored in the storage part (not graphically illustrated) provided in the storage part 71 or the like. These stored electric potentials (electric potential values) are used in making comparisons with electric potentials to be detected next time.

Thereby, the position detecting method of the touchscreen panel according to this embodiment ends. According to this embodiment, by repeatedly performing the operation of step S102 through step S112, it is possible to determine the direction or distance of movement of contact points, and based on this information, it is possible to enlarge, reduce, or rotate an image displayed on the display screen.

In the position detecting method described above, a description is given of the case of detecting the direction of movement or the like of two contact points, that is, detecting a so-called gesture function. By the above-described method, the coordinate positions of two contact points may be detected based on the electric potentials detected in the first electric potential detecting part 31, the second electric potential detecting part 32, the third electric potential detecting part 41, and the fourth electric potential detecting part 42. In this case, in step S112, the coordinate positions of the two contact points are stored in addition to the electric potentials detected in the first electric potential detecting part 31, the second electric potential detecting part 32, the third electric potential detecting part 41, and the fourth electric potential detecting part 42.

### [Movement of Contact Points]

Next, a description is given of a detection method in the case where two contact points move according to the touchscreen panel of this embodiment.

In the case of two contact points, if it is possible to obtain the direction and the distance of movement of the contact points as information, it is possible to control the touchscreen panel based on this information. In the case of a single contact point, the movement of the contact point may be detected by detecting coordinate positions of the contact point.

For example, a description is given of the case of detecting the direction of movement, etc., of the contact positions of two points in contact with the touchscreen panel based on the above-described comparisons of step S110, that is, by comparing the electric potentials detected at the previous time by the first electric potential detecting part 31, the second electric potential detecting part 32, the third electric potential detecting part 41, and the fourth electric potential detecting part 42 with the electric potentials detected at the present time by the first electric potential detecting part 31, the second electric potential detecting part 32, the third electric potential detecting part 41, and the fourth electric potential detecting part 42. If the position information of the two contact points has been detected, it is also possible to detect the direction of movement, etc., of the contact positions based on the position information of the two contact points.

[Case where Point A and Point B Approach Each Other]

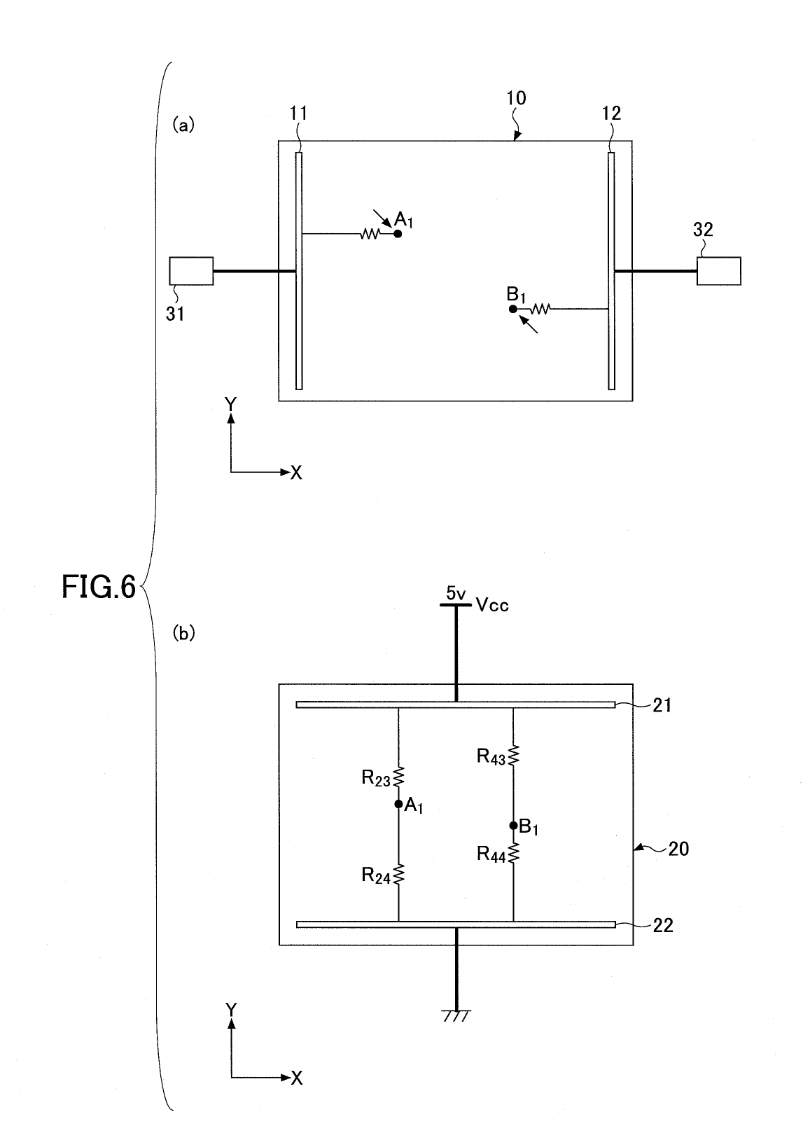

A description is given, with reference to FIG. 5 and FIG. 6, of a case where Point A and Point B that are contact points on the touchscreen panel move closer to (move toward) each other from their positions illustrated in FIG. 2 and FIG. 3.

First, as illustrated in FIG. 5, in the touchscreen panel having the structure illustrated in FIG. 1, the switches 51 and 52 are turned ON and the switches 61 and 62 are turned OFF. As a result, a voltage of 5 V is applied to the first upper electrode 11, and the second upper electrode 12 is grounded, so that an electric potential distribution having a gradient in an X-axis direction is generated in the upper resistive film 10.

It is assumed that in this state, the contact points on the touchscreen panel have moved from Point A and Point B illustrated in FIG. 2 to Point A₁ and Point B₁ illustrated in FIG. 5. In this case, the electric potential at Point A₁ is a value obtained by dividing a voltage between a resistance component R₁₃ and a resistance component R₁₄, that is, 5×R₁₄/(R₁₃+R₁₄) V. Further, the electric potential at Point B₁ is a value obtained by dividing a voltage between a resistance component R₃₃ and a resistance component R₃₄, that is, 5×R₃₄/(R₃₃+R₃₄) V. Here, (R₁₁+R₁₂) and (R₁₃+R₁₄) are equal in value, and (R₃₁+R₃₂) and (R₃₃+R₃₄) are equal in value.

Here, as illustrated in FIG. 5, the movements of the two contact points to Point A₁ and Point B₁ cause the resistance component R₁₄ to be lower in resistance value than the resistance component R₁₂ and cause the resistance component R₃₄ to be higher in resistance value than the resistance component R₃₂. In response to this, in the lower resistive film 20, the electric potential detected in the third electric potential detecting part 41 via the first lower electrode 21 is lower and the electric potential detected in the fourth electric potential detecting part 42 via the second lower electrode 22 is higher than in the case where the contact points are Point A and Point B. This makes it possible to detect that the two contact points have moved closer to each other in the X-axis directions from the contact points of Point A and Point B illustrated in FIG. 2 to the contact points of Point A₁ and Point B₁ illustrated in FIG. 5.

Next, as illustrated in FIG. 6, in the touchscreen panel having the structure illustrated in FIG. 1, the switches 51 and 52 are turned OFF and the switches 61 and 62 are turned ON. As a result, a voltage of 5 V is applied to the first lower electrode 21, and the second lower electrode 22 is grounded, so that an electric potential distribution having a gradient in a Y-axis direction is generated in the lower resistive film 20.

It is assumed that in this state, the contact points on the touchscreen panel have moved from Point A and Point B illustrated in FIG. 3 to Point A₁ and Point B₁ illustrated in FIG. 6. In this case, the electric potential at Point A₁ is a value obtained by dividing a voltage between a resistance component R₂₃ and a resistance component R₂₄, that is, 5×R₂₄/(R₂₃+R₂₄) V. Further, the electric potential at Point B₁ is a value obtained by dividing a voltage between a resistance component R₄₃ and a resistance component R₄₄, that is, 5×R₄₄/(R₄₃+R₄₄) V. Here, (R₂₁+R₂₂) and (R₂₃+R₂₄) are equal in value, and (R₄₁+R₄₂) and (R₄₃+R₄₄) are equal in value.

Here, as illustrated in FIG. 6, the movements of the two contact points to Point A₁ and Point B₁ cause the resistance component R₂₄ to be lower in resistance value than the resistance component R₂₂ and cause the resistance component R₄₄ to be higher in resistance value than the resistance component R₄₂. In response to this, in the upper resistive film 10, the electric potential detected in the first electric potential detecting part 31 via the first upper electrode 11 is lower and the electric potential detected in the second electric potential detecting part 32 via the second upper electrode 12 is higher than in the case where the contact points are Point A and Point B. This makes it possible to detect that the two contact points have moved closer to each other in the Y-axis directions from the contact points of Point A and Point B illustrated in FIG. 3 to the contact points of Point A₁ and Point B₁ illustrated in FIG. 6.

Based on the above information, it is possible to determine that Point A₁ and Point B₁ are closer to each other in the X-axis directions and the Y-axis directions than (relative to the state of) Point A and Point B (that is, Point A and Point B have moved closer to each other in the X-axis directions and the Y-axis directions to Point A₁ and Point B₁).

[Case where Point A and Point B Move Away from Each Other]

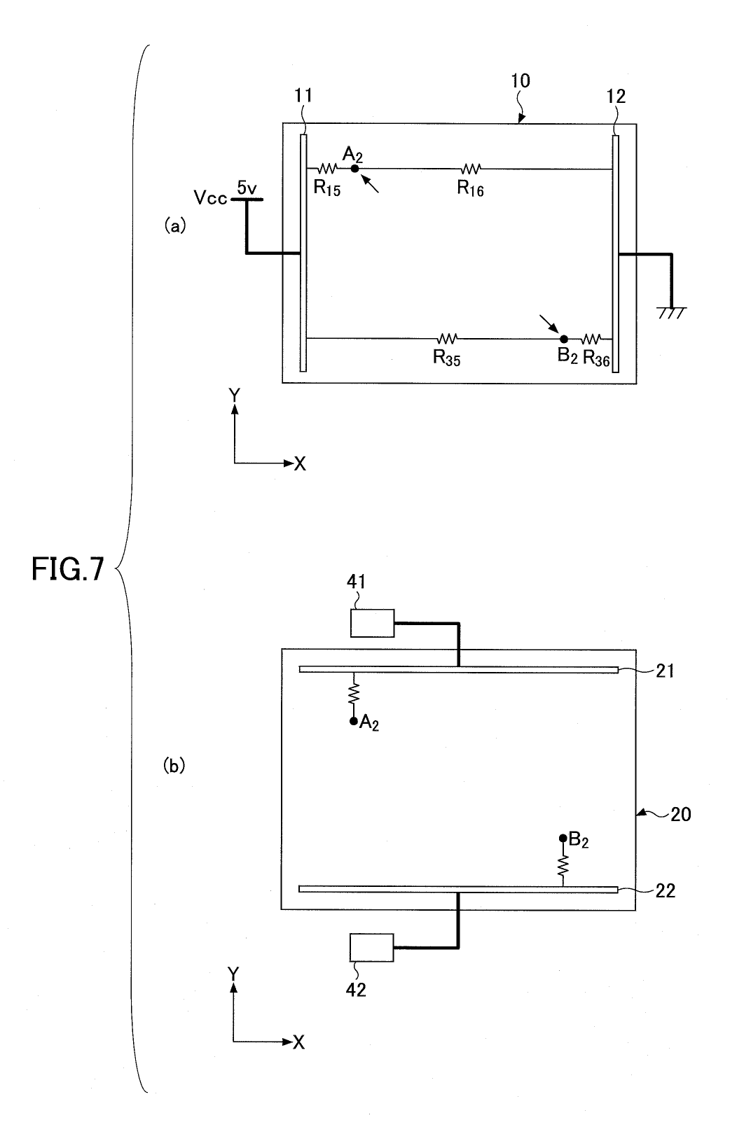

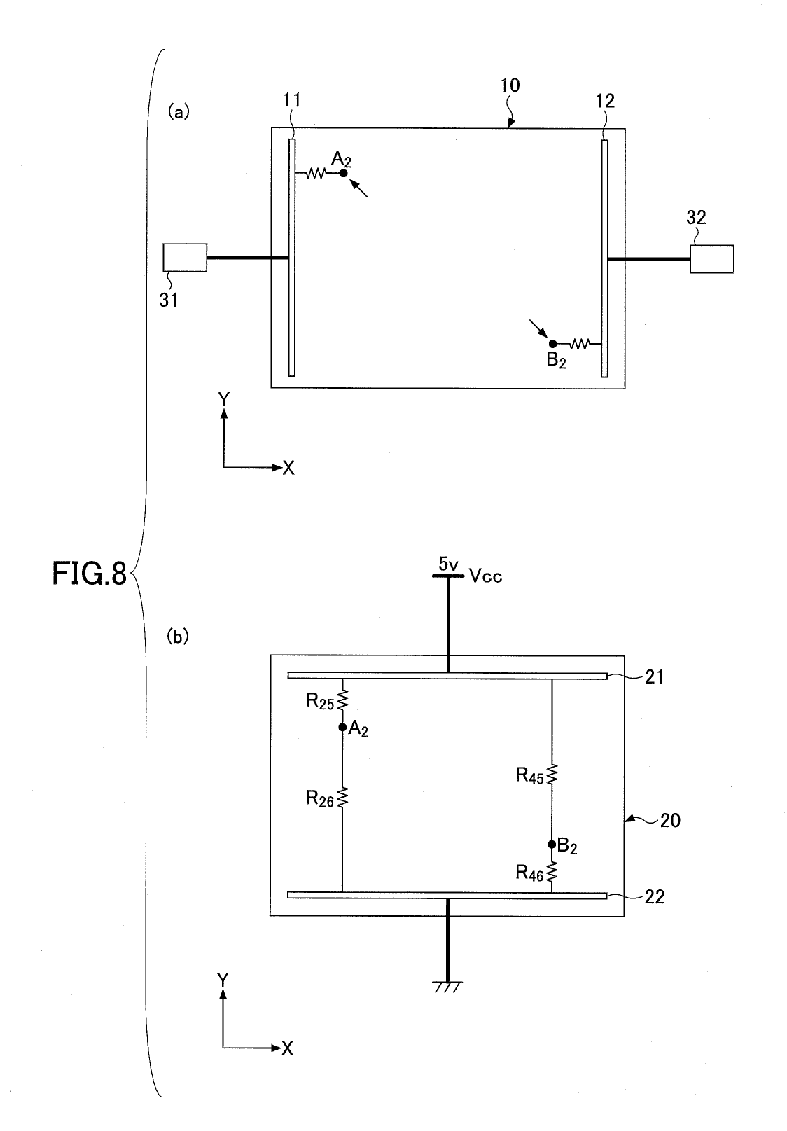

Next, a description is given, with reference to FIG. 7 and FIG. 8, of a case where Point A and Point B that are contact points on the touchscreen panel move away from each other from their positions illustrated in FIG. 2 and FIG. 3.

First, as illustrated in FIG. 7, in the touchscreen panel having the structure illustrated in FIG. 1, the switches 51 and 52 are turned ON and the switches 61 and 62 are turned OFF. As a result, a voltage of 5 V is applied to the first upper electrode 11, and the second upper electrode 12 is grounded, so that an electric potential distribution having a gradient in an X-axis direction is generated in the upper resistive film 10.

It is assumed that in this state, the contact points on the touchscreen panel have moved from Point A and Point B illustrated in FIG. 2 to Point A₂ and Point B₂ illustrated in FIG. 7. In this case, the electric potential at Point A₂ is a value obtained by dividing a voltage between a resistance component R₁₅ and a resistance component R₁₆, that is, 5×R₁₆/(R₁₅+R₁₆) V. Further, the electric potential at Point B₂ is a value obtained by dividing a voltage between a resistance component R₃₅ and a resistance component R₃₆, that is, 5×R₃₆/(R₃₅+R₃₆) V. Here, (R₁₁+R₁₂) and (R₁₅+R₁₆) are equal in value, and (R₃₁+R₃₂) and (R₃₅+R₃₆) are equal in value.

Here, as illustrated in FIG. 7, the movements of the two contact points to Point A₂ and Point B₂ cause the resistance component R₁₆ to be higher in resistance value than the resistance component R₁₂ and cause the resistance component R₃₆ to be lower in resistance value than the resistance component R₃₂. In response to this, in the lower resistive film 20, the electric potential detected in the third electric potential detecting part 41 via the first lower electrode 21 is higher and the electric potential detected in the fourth electric potential detecting part 42 via the second lower electrode 22 is lower than in the case where the contact points are Point A and Point B. This makes it possible to detect that the two contact points have moved away from each other in the X-axis directions from the contact points of Point A and Point B illustrated in FIG. 2 to the contact points of Point A₂ and Point B₂ illustrated in FIG. 7.

Next, as illustrated in FIG. 8, in the touchscreen panel having the structure illustrated in FIG. 1, the switches 51 and 52 are turned OFF and the switches 61 and 62 are turned ON. As a result, a voltage of 5 V is applied to the first lower electrode 21, and the second lower electrode 22 is grounded, so that an electric potential distribution having a gradient in a Y-axis direction is generated in the lower resistive film 20.

It is assumed that in this state, the contact points on the touchscreen panel have moved from Point A and Point B illustrated in FIG. 3 to Point A₂ and Point B₂ illustrated in FIG. 8. In this case, the electric potential at Point A₂ is a value obtained by dividing a voltage between a resistance component R₂₅ and a resistance component R₂₆, that is, 5×R₂₆/(R₂₅+R₂₆) V. Further, the electric potential at Point B₂ is a value obtained by dividing a voltage between a resistance component R₄₅ and a resistance component R₄₆, that is, 5×R₄₆/(R₄₅+R₄₆) V. Here, (R₂₁+R₂₂) and (R₂₅+R₂₆) are equal in value, and (R₄₁+R₄₂) and (R₄₅+R₄₆) are equal in value.

Here, as illustrated in FIG. 8, the movements of the two contact points to Point A₂ and Point B₂ cause the resistance component R₂₆ to be higher in resistance value than the resistance component R₂₂ and cause the resistance component R₄₆ to be lower in resistance value than the resistance component R₄₂. In response to this, in the upper resistive film 10, the electric potential detected in the first electric potential detecting part 31 via the first upper electrode 11 is higher and the electric potential detected in the second electric potential detecting part 32 via the second upper electrode 12 is lower than in the case where the contact points are Point A and Point B. This makes it possible to detect that the two contact points have moved closer to each other in the Y-axis directions from the contact points of Point A and Point B illustrated in FIG. 3 to the contact points of Point A₂ and Point B₂ illustrated in FIG. 8.

Based on the above information, it is possible to determine that Point A₂ and Point B₂ are more remote from each other in the X-axis directions and the Y-axis directions than (relative to the state of) Point A and Point B (that is, Point A and Point B have moved away from each other in the X-axis directions and the Y-axis directions to Point A₂ and Point B₂).

[Case where Point A and Point B Rotate Counterclockwise]

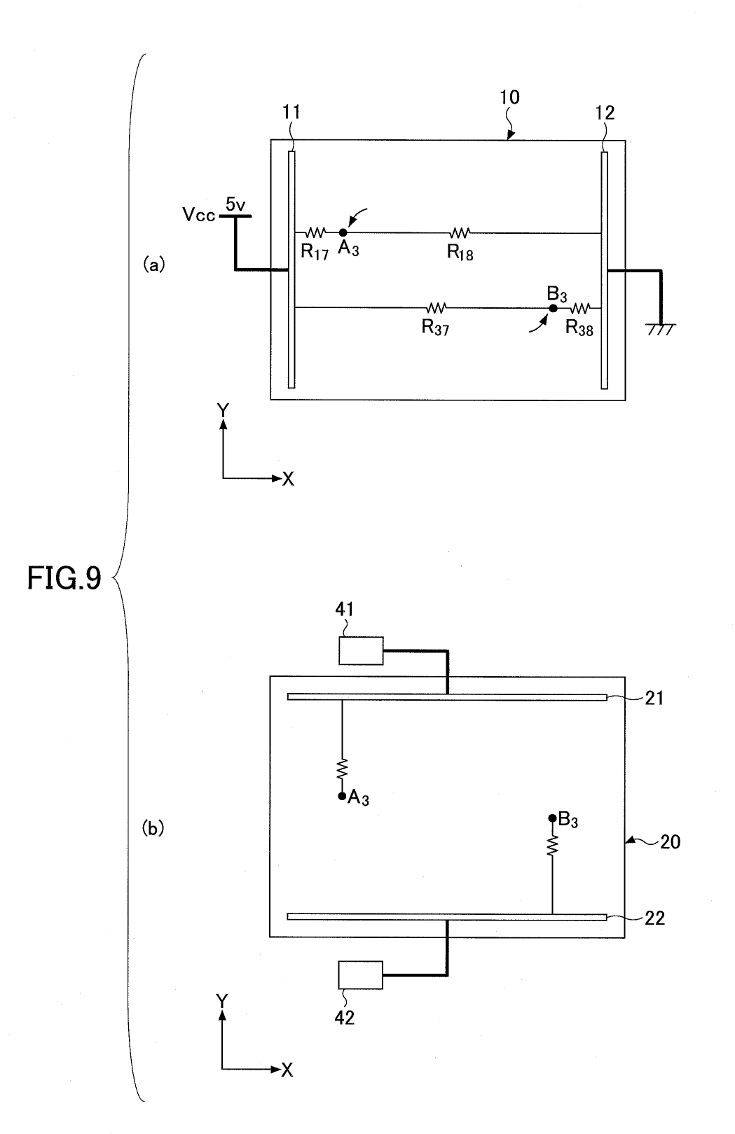

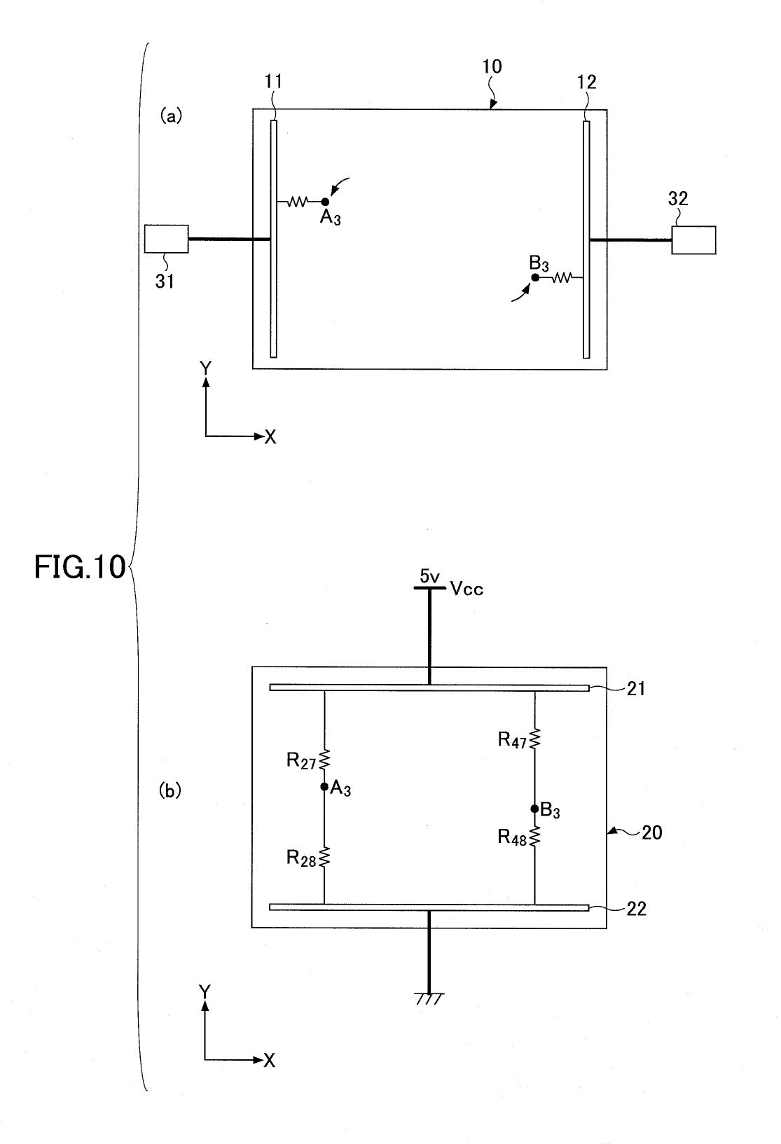

Next, a description is given, with reference to FIG. 9 and FIG. 10, of a case where Point A and Point B that are contact points on the touchscreen panel rotate counterclockwise from their positions illustrated in FIG. 2 and FIG. 3.

First, as illustrated in FIG. 9, in the touchscreen panel having the structure illustrated in FIG. 1, the switches 51 and 52 are turned ON and the switches 61 and 62 are turned OFF. As a result, a voltage of 5 V is applied to the first upper electrode 11, and the second upper electrode 12 is grounded, so that an electric potential distribution having a gradient in an X-axis direction is generated in the upper resistive film 10.

It is assumed that in this state, the contact points on the touchscreen panel have moved from Point A and Point B illustrated in FIG. 2 to Point A₃ and Point B₃ illustrated in FIG. 9. In this case, the electric potential at Point A₃ is a value obtained by dividing a voltage between a resistance component R₁₇ and a resistance component R₁₈, that is, 5×R₁₈/(R₁₇+R₁₈) V. Further, the electric potential at Point B₃ is a value obtained by dividing a voltage between a resistance component R₃₇ and a resistance component R₃₈, that is, 5×R₃₈/(R₃₇+R₃₈) V. Here, (R₁₁+R₁₂) and (R₁₇+R₁₈) are equal in value, and (R₃₁+R₃₂) and (R₃₇+R₃₈) are equal in value.

Here, as illustrated in FIG. 9, the movements of the two contact points to Point A₃ and Point B₃ cause the resistance component R₁₈ to be higher in resistance value than the resistance component R₁₂, and cause the resistance component R₃₈ to be lower in resistance value than the resistance component R₃₂. In response to this, in the lower resistive film 20, the electric potential detected in the third electric potential detecting part 41 via the first lower electrode 21 is higher and the electric potential detected in the fourth electric potential detecting part 42 via the second lower electrode 22 is lower than in the case where the contact points are Point A and Point B. This makes it possible to detect that in the X-axis directions, the two contact points have moved away from each other from the contact points of Point A and Point B illustrated in FIG. 2 to the contact points of Point A₃ and Point B₃ illustrated in FIG. 9.

Next, as illustrated in FIG. 10, in the touchscreen panel having the structure illustrated in FIG. 1, the switches 51 and 52 are turned OFF and the switches 61 and 62 are turned ON. As a result, a voltage of 5 V is applied to the first lower electrode 21, and the second lower electrode 22 is grounded, so that an electric potential distribution having a gradient in a Y-axis direction is generated in the lower resistive film 20.

It is assumed that in this state, the contact points on the touchscreen panel have moved from Point A and Point B illustrated in FIG. 3 to Point A₃ and Point B₃ illustrated in FIG. 10. In this case, the electric potential at Point A₃ is a value obtained by dividing a voltage between a resistance component R₂₇ and a resistance component R₂₈, that is, 5×R₂₈/(R₂₇+R₂₈) V. Further, the electric potential at Point B₃ is a value obtained by dividing a voltage between a resistance component R₄₇ and a resistance component R₄₈, that is, 5×R₄₈/(R₄₇+R₄₈) V. Here, (R₂₁+R₂₂) and (R₂₇+R₂₈) are equal in value, and (R₄₁+R₄₂) and (R₄₇+R₄₈) are equal in value.

Here, as illustrated in FIG. 10, the movements of the two contact points to Point A₃ and Point B₃ cause the resistance component R₂₈ to be lower in resistance value than the resistance component R₂₂ and cause the resistance component R₄₈ to be higher in resistance value than the resistance component R₄₂. In response to this, in the upper resistive film 10, the electric potential detected in the first electric potential detecting part 31 via the first upper electrode 11 is lower and the electric potential detected in the second electric potential detecting part 32 via the second upper electrode 12 is higher than in the case where the contact points are Point A and Point B. This makes it possible to detect that in the Y-axis directions, the two contact points have moved closer to each other from the contact points of Point A and Point B illustrated in FIG. 3 to the contact points of Point A₃ and Point B₃ illustrated in FIG. 10.

Based on the above information, it is possible to determine that Point A and Point B have rotated counterclockwise to Point A₃ and Point B₃.

[Case where Point A and Point B Rotate Clockwise]

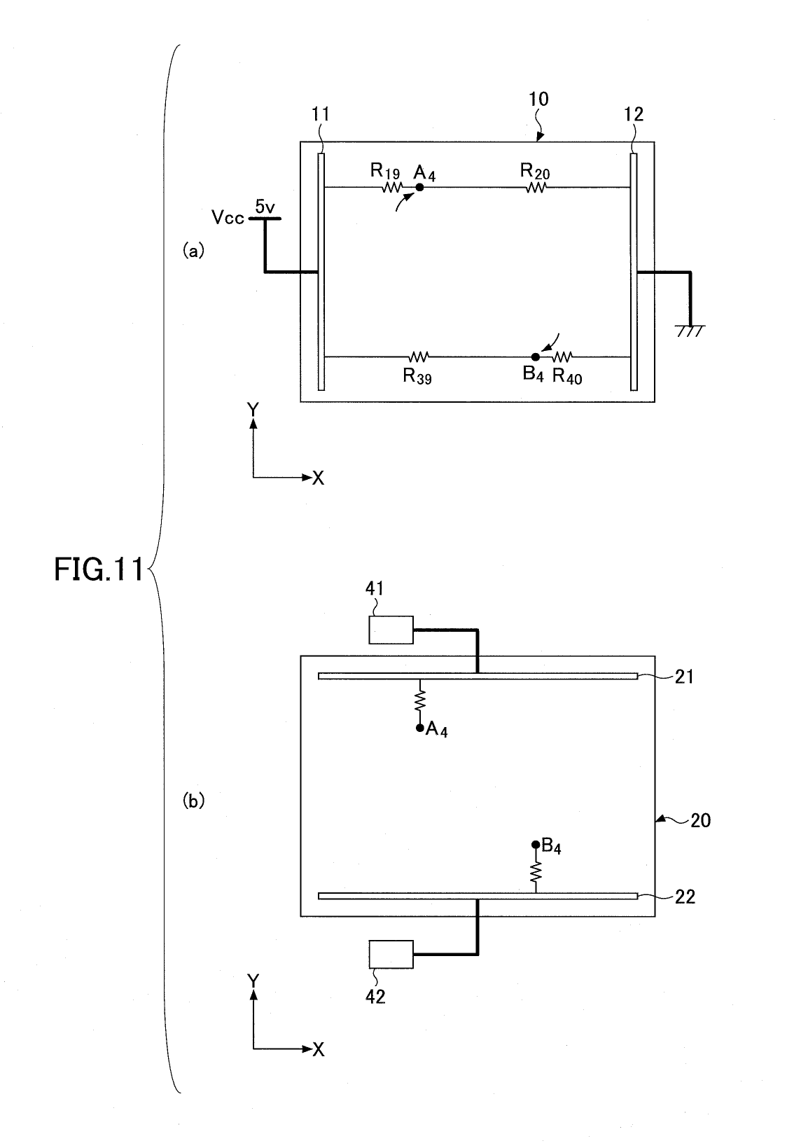

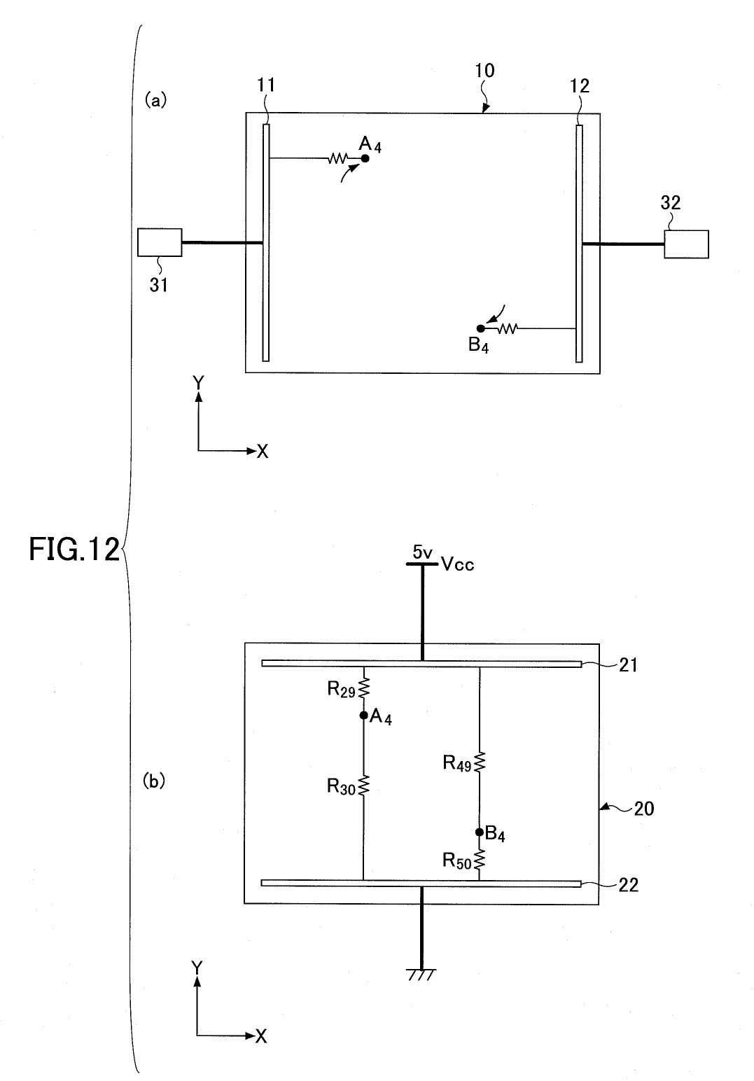

Next, a description is given, with reference to FIG. 11 and FIG. 12, of a case where Point A and Point B that are contact points on the touchscreen panel rotate clockwise from their positions illustrated in FIG. 2 and FIG. 3.

First, as illustrated in FIG. 11, in the touchscreen panel having the structure illustrated in FIG. 1, the switches 51 and 52 are turned ON and the switches 61 and 62 are turned OFF. As a result, a voltage of 5 V is applied to the first upper electrode 11, and the second upper electrode 12 is grounded, so that an electric potential distribution having a gradient in an X-axis direction is generated in the upper resistive film 10.

It is assumed that in this state, the contact points on the touchscreen panel have moved from Point A and Point B illustrated in FIG. 2 to Point A₄ and Point B₄ illustrated in FIG. 11. In this case, the electric potential at Point A₄ is a value obtained by dividing a voltage between a resistance component R₁₉ and a resistance component R₂₀, that is, 5×R₂₀/(R₁₉+R₂₀) V. Further, the electric potential at Point B₄ is a value obtained by dividing a voltage between a resistance component R₃₉ and a resistance component R₄₀, that is, 5×R₄₀/(R₃₉+R₄₀) V. Here, (R₁₁+R₁₂) and (R₁₉+R₂₀) are equal in value, and (R₃₁+R₃₂) and (R₃₉+R₄₀) are equal in value.

Here, as illustrated in FIG. 11, the movements of the two contact points to Point A₄ and Point B₄ cause the resistance component R₂₀ to be lower in resistance value than the resistance component R₁₂, and cause the resistance component R₄₀ to be higher in resistance value than the resistance component R₃₂. In response to this, in the lower resistive film 20, the electric potential detected in the third electric potential detecting part 41 via the first lower electrode 21 is lower and the electric potential detected in the fourth electric potential detecting part 42 via the second lower electrode 22 is higher than in the case where the contact points are Point A and Point B. This makes it possible to detect that in the X-axis directions, the two contact points have moved closer to each other from the contact points of Point A and Point B illustrated in FIG. 2 to the contact points of Point A₄ and Point B₄ illustrated in FIG. 11.

Next, as illustrated in FIG. 12, in the touchscreen panel having the structure illustrated in FIG. 1, the switches 51 and 52 are turned OFF and the switches 61 and 62 are turned ON. As a result, a voltage of 5 V is applied to the first lower electrode 21, and the second lower electrode 22 is grounded, so that an electric potential distribution having a gradient in a Y-axis direction is generated in the lower resistive film 20.

It is assumed that in this state, the contact points on the touchscreen panel have moved from Point A and Point B illustrated in FIG. 3 to Point A₄ and Point B₄ illustrated in FIG. 12. In this case, the electric potential at Point A₄ is a value obtained by dividing a voltage between a resistance component R₂₉ and a resistance component R₃₀, that is, 5×R₃₀/(R₂₉+R₃₀) V. Further, the electric potential at Point B₄ is a value obtained by dividing a voltage between a resistance component R₄₉ and a resistance component R₅₀, that is, 5×R₅₀/(R₄₉+R₅₀) V. Here, (R₂₁+R₂₂) and (R₂₉+R₃₀) are equal in value, and (R₄₁+R₄₂) and (R₄₉+R₅₀) are equal in value.

Here, as illustrated in FIG. 12, the movements of the two contact points to Point A₄ and Point B₄ cause the resistance component R₃₀ to be higher in resistance value than the resistance component R₂₂ and cause the resistance component R₅₀ to be lower in resistance value than the resistance component R₄₂. In response to this, in the upper resistive film 10, the electric potential detected in the first electric potential detecting part 31 via the first upper electrode 11 is higher and the electric potential detected in the second electric potential detecting part 32 via the second upper electrode 12 is lower than in the case where the contact points are Point A and Point B. This makes it possible to detect that in the Y-axis directions, the two contact points have moved away from each other from the contact points of Point A and Point B illustrated in FIG. 3 to the contact points of Point A₄ and Point B₄ illustrated in FIG. 12.

Based on the above information, it is possible to determine that Point A and Point B have rotated clockwise to Point A₄ and Point B₄.

Thus, it is possible to input information based on position information or the movement of contact points in the case where the number of contact points on the touchscreen panel is two. That is, in the case where the number of contact points is two, it is possible to input information based on a so-called gesture function such as approaching, moving away, or rotation.

### [b] Second Embodiment

Next, a description is given of a second embodiment according to the present invention.

According to a touchscreen panel of this embodiment, each of a first upper electrode, a second upper electrode, a first lower electrode, and a second lower electrode has a divided structure, and each of the divided electrodes is provided with an electric potential detecting part.

### [Structure of Touchscreen Panel]

First, a description is given of a structure of the touchscreen panel according to this embodiment.

The touchscreen panel according to this embodiment includes an upper resistive film 110 and a lower resistive film 120. Each of the upper resistive film 110 and the lower resistive film 120 is formed of a transparent electrically conductive film of ITO or the like, and has a substantially square or substantially rectangular shape. Each of the upper resistive film 110 and the lower resistive film 120 may be formed on the surface of a glass substrate, a transparent film or the like. For example, the upper resistive film 110 may be formed on a transparent film and the lower resistive film 120 may be formed on a glass substrate. In such a case, the upper resistive film 110 and the lower resistive film 120 are so arranged as to face each other.

A first upper electrode 111 and a second upper electrode 112 are formed along the Y-axis directions at a first end in the X-axis directions on the upper resistive film 110. A third upper electrode 113 and a fourth upper electrode 114 are formed along the Y-axis directions at a second end in the X-axis directions on the upper resistive film 110. Further, a first lower electrode 121 and a second lower electrode 122 are formed along the X-axis directions at a first end in the Y-axis directions on the lower resistive film 120. A third lower electrode 123 and a fourth lower electrode 124 are formed along the X-axis directions at a second end in the Y-axis directions on the lower resistive film 120.

The first upper electrode 111 is connected to a first electric potential detecting part 131 configured to detect an electric potential at the first upper electrode 111. The second upper electrode 112 is connected to a second electric potential detecting part 132 configured to detect an electric potential at the second upper electrode 112. Each of the first upper electrode 111 and the second upper electrode 112 is also connected to a power supply potential (supply voltage) Vcc via a switch 151. According to this embodiment, the power supply potential Vcc is 5 V.

The third upper electrode 113 is connected to a third electric potential detecting part 133 configured to detect an electric potential at the third upper electrode 113. The fourth upper electrode 114 is connected to a fourth electric potential detecting part 134 configured to detect an electric potential at the fourth upper electrode 114. Each of the third upper electrode 113 and the fourth upper electrode 114 is grounded via a switch 152. According to this embodiment, the ground potential is 0 V.

The first lower electrode 121 is connected to a fifth electric potential detecting part 141 configured to detect an electric potential at the first lower electrode 121. The second lower electrode 122 is connected to a sixth electric potential detecting part 142 configured to detect an electric potential at the second lower electrode 122. Each of the first lower electrode 121 and the second lower electrode 122 is also connected to the power supply potential Vcc via a switch 161.

The third lower electrode 123 is connected to a seventh electric potential detecting part 143 configured to detect an electric potential at the third lower electrode 123. The fourth lower electrode 124 is connected to an eighth electric potential detecting part 144 configured to detect an electric potential at the fourth lower electrode 124. Each of the third lower electrode 123 and the fourth lower electrode 124 is grounded via a switch 162.

The first electric potential detecting part 131, the second electric potential detecting part 132, the third electric potential detecting part 133, the fourth electric potential detecting part 134, the fifth electric potential detecting part 141, the sixth electric potential detecting part 142, the seventh electric potential detecting part 143, and the eighth electric potential detecting part 144 are connected to a control part 171. The control part 171 performs control based on the electric potentials detected in the first electric potential detecting part 131, the second electric potential detecting part 132, the third electric potential detecting part 133, the fourth electric potential detecting part 134, the fifth electric potential detecting part 141, the sixth electric potential detecting part 142, the seventh electric potential detecting part 143, and the eighth electric potential detecting part 144. Further, the control part 171 also performs ON-OFF control of the switches 151, 152, 161, and 162 via interconnects (not graphically illustrated).

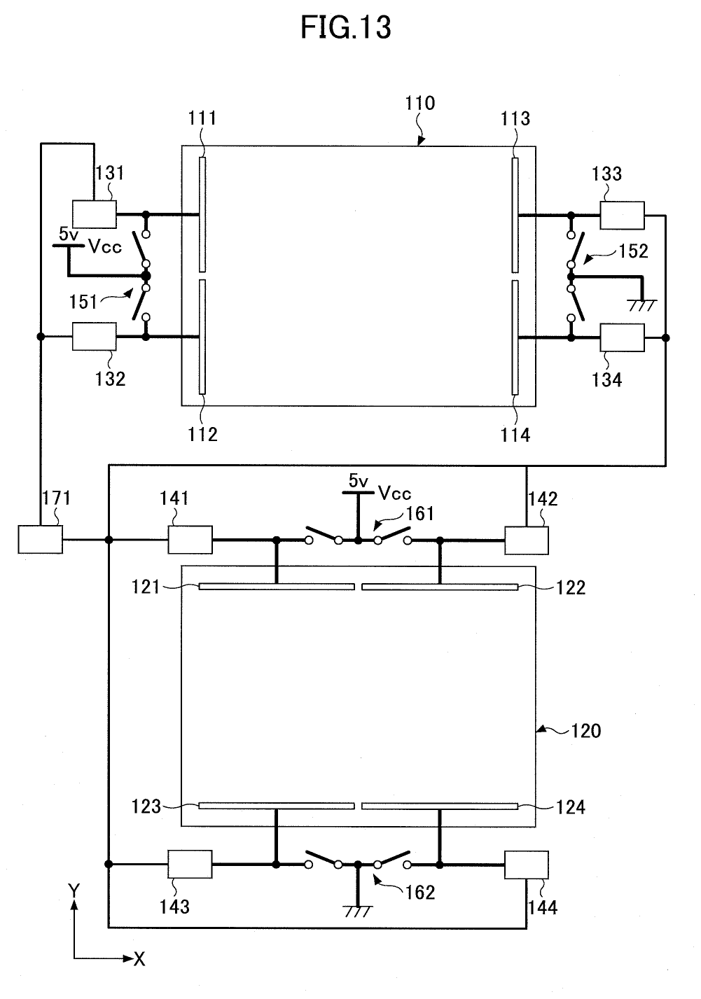

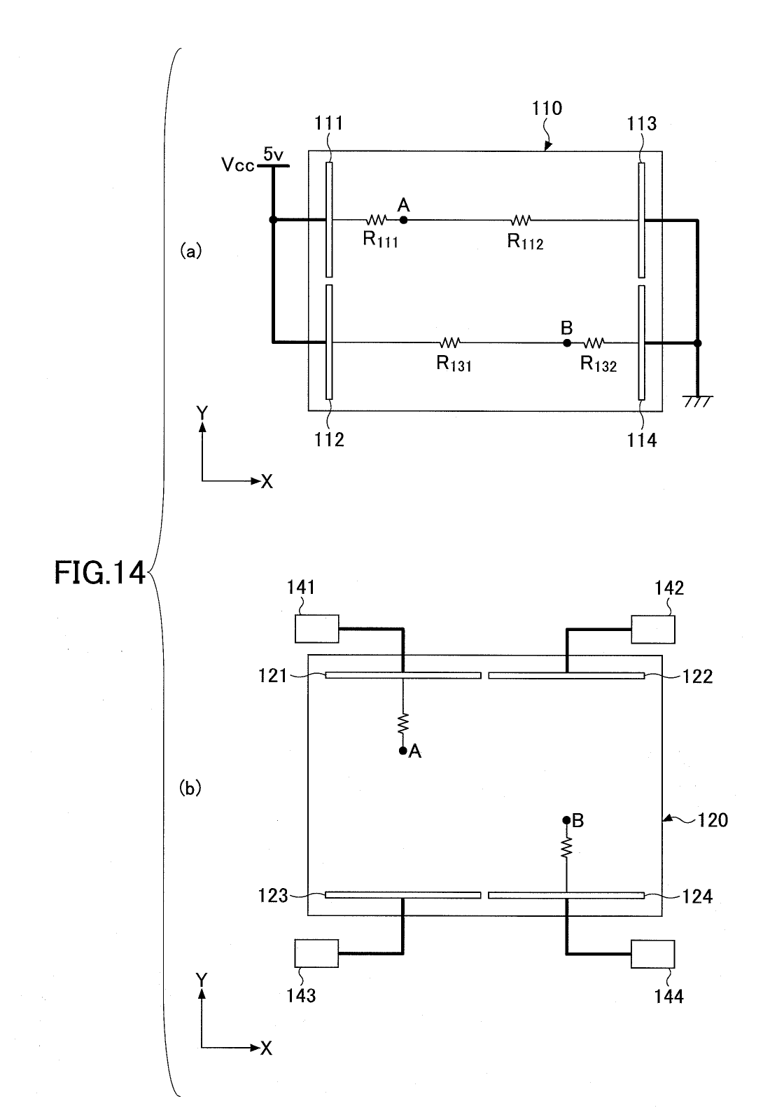

In FIG. 13, the upper resistive film 110 and the lower resistive film 120 are illustrated as being separated for convenience of description. According to the touchscreen panel of this embodiment, however, the upper resistive film 110 is provided on the lower resistive film 120. The same applies to the subsequent drawings. Further, in FIG. 14 through FIG. 19, (a) illustrates the upper resistive film 110 and (b) illustrates the lower resistive film 120.

### [Position Detection in X-axis Directions]

In the touchscreen panel according to this embodiment, first, an electric potential distribution is formed in the upper resistive film 110, and electric potentials are measured via the lower resistive film 120.

For example, in the touchscreen panel having the structure illustrated in FIG. 13, the switches 151 and 152 are turned ON and the switches 161 and 162 are turned OFF. As a result, as illustrated in FIG. 14, a voltage of 5 V is applied to the first upper electrode 111 and the second upper electrode 112, and the third upper electrode 113 and the fourth upper electrode 114 are grounded, so that an electric potential distribution having a gradient in an X-axis direction is generated in the upper resistive film 110.

In this state, for example, it is assumed that contact is made at two Points A and B on the touchscreen panel. In this case, the electric potential at Point A is a value obtained by dividing a voltage between a resistance component R₁₁₁ and a resistance component R₁₁₂, that is, 5×R₁₁₂/(R₁₁₁+R₁₁₂) V. Further, the electric potential at Point B is a value obtained by dividing a voltage between a resistance component R₁₃₁ and a resistance component R₁₃₂, that is, 5×R₁₃₂/(R₁₃₁+R₁₃₂) V.

These electric potentials are detected via the lower resistive film 120, and in general, an electric potential at the midpoint between Point A and Point B is supposed to be detected. However, since the lower resistive film 120 has a resistance component, the potentials at Point A and Point B strongly affect the closer of the first or second lower electrode 121 or 122 and the third or fourth lower electrode 123 or 124.

That is, in the case illustrated in FIG. 14, the first lower electrode 121 is closer than the third lower electrode 123 at Point A and the fourth lower electrode 124 is closer than the second lower electrode 122 at Point B. In this case, the effect of Point A is dominant in the electric potential detected at the first lower electrode 121, and the effect of Point B is dominant in the electric potential detected at the fourth lower electrode 124.

In other words, comparing the resistance component between Point A and the first lower electrode 121 and the resistance component between Point A and the third lower electrode 123, the resistance value is lower in the resistance component between Point A and the first lower electrode 121. Accordingly, the first lower electrode 121 is strongly affected by the electric potential at Point A. Comparing the resistance component between Point B and the second lower electrode 122 and the resistance component between Point B and the fourth lower electrode 124, the resistance value is lower in the resistance component between Point B and the fourth lower electrode 124. Accordingly, the fourth lower electrode 124 is strongly affected by the electric potential at Point B.

Thus, different values are detected for the electric potential detected in the fifth electric potential detecting part 141 via the first lower electrode 121 and the electric potential detected in the eighth electric potential detecting part 144 via the fourth lower electrode 124.

On the other hand, if contact is made at a single point with voltage applied in the same manner, the electric potentials detected in the fifth electric potential detecting part 141 through the eighth electric potential detecting part 144 are substantially equal in value. Accordingly, a determination as to whether the electric potentials detected in the fifth electric potential detecting part 141 through the eighth electric potential detecting part 144 are substantially equal may be used to determine whether the number of contact points is one or two.

Further, as described above, the electric potential at Point A is a value obtained by dividing a voltage between the resistance component R₁₁₁ and the resistance component R₁₁₂, and the electric potential at Point B is a value obtained by dividing a voltage between the resistance component R₁₃₁ and the resistance component R₁₃₂. Therefore, it is also possible to detect x coordinate positions at Point A and Point B based on the electric potential detected in the fifth electric potential detecting part 141 and the electric potential detected in the eighth electric potential detecting part 144.

For example, the correlation between the x coordinate positions at two contact points and the electric potentials detected in the fifth electric potential detecting part 141 through the eighth electric potential detecting part 144 may be studied in advance, and the x coordinate positions at Point A and Point B may be detected (determined) from the electric potentials detected in the fifth electric potential detecting part 141 through the eighth electric potential detecting part 144 based on the correlation.

### [Position Detection in Y-axis Directions]

Next, in the touchscreen panel according to this embodiment, an electric potential distribution is formed in the lower resistive film 120, and electric potentials are measured via the upper resistive film 110.

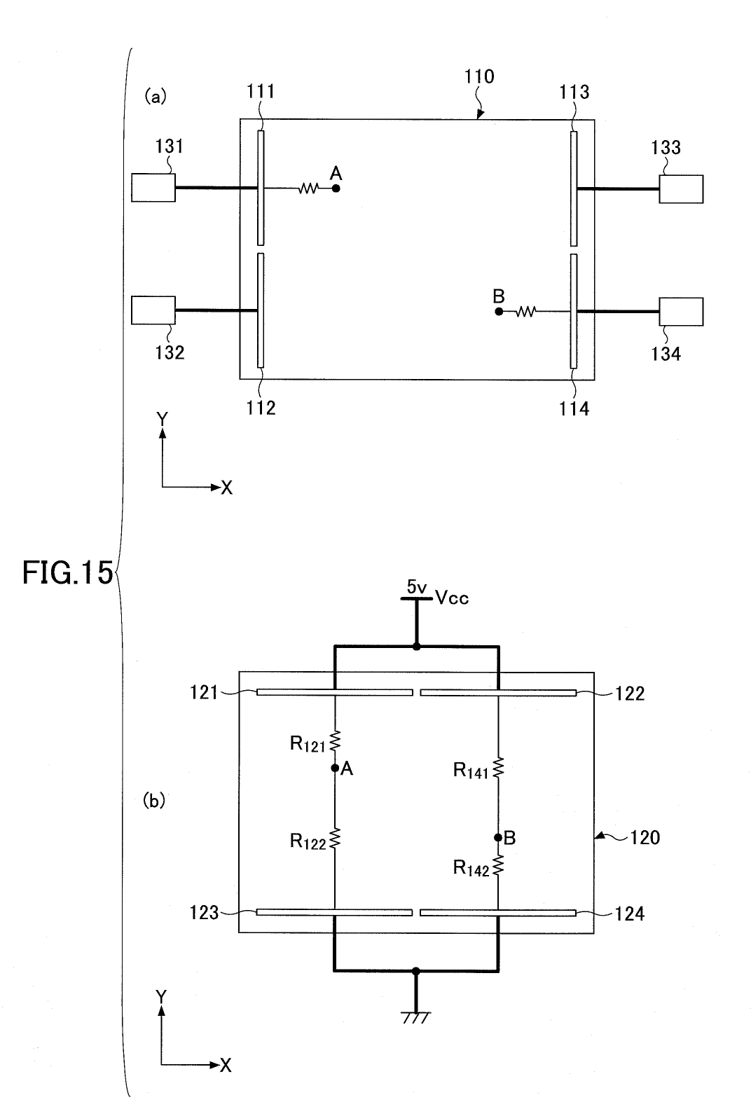

For example, in the touchscreen panel having the structure illustrated in FIG. 13, the switches 151 and 152 are turned OFF and the switches 161 and 162 are turned ON. As a result, as illustrated in FIG. 15, a voltage of 5 V is applied to the first lower electrode 121 and the second lower electrode 122, and the third lower electrode 123 and the fourth lower electrode 124 are grounded, so that an electric potential distribution having a gradient in a Y-axis direction is generated in the lower resistive film 120.

In this state, for example, it is assumed that contact is made at two Points A and B on the touchscreen panel. In this case, the electric potential at Point A is a value obtained by dividing a voltage between a resistance component R₁₂₁ and a resistance component R₁₂₂, that is, 5×R₁₂₂/(R₁₂₁+R₁₂₂) V. Further, the electric potential at Point B is a value obtained by dividing a voltage between a resistance component R₁₄₁ and a resistance component R₁₄₂, that is, 5×R₁₄₂/(R₁₄₁+R₁₄₂) V.

These electric potentials are detected via the upper resistive film 110, and in general, an electric potential at the midpoint between Point A and Point B is supposed to be detected. However, since the upper resistive film 110 has a resistance component, the potentials at Point A and Point B strongly affect the closer of the first or second upper electrode 111 or 112 and the third or fourth upper electrode 113 or 114.

That is, in the case illustrated in FIG. 15, the first upper electrode 111 is closer than the third upper electrode 113 at Point A and the fourth upper electrode 114 is closer than the second upper electrode 112 at Point B. In this case, the effect of Point A is dominant in the electric potential detected at the first upper electrode 111, and the effect of Point B is dominant in the electric potential detected at the fourth upper electrode 114.

In other words, comparing the resistance component between Point A and the first upper electrode 111 and the resistance component between Point A and the third upper electrode 113, the resistance value is lower in the resistance component between Point A and the first upper electrode 111. Accordingly, the first upper electrode 111 is strongly affected by the electric potential at Point A. Comparing the resistance component between Point B and the second upper electrode 112 and the resistance component between Point B and the fourth upper electrode 114, the resistance value is lower in the resistance component between Point B and the fourth upper electrode 114. Accordingly, the fourth upper electrode 114 is strongly affected by the electric potential at Point B.

Thus, different values are detected for the electric potential detected in the first electric potential detecting part 131 via the first upper electrode 111 and the electric potential detected in the fourth electric potential detecting part 134 via the fourth upper electrode 114.

On the other hand, if contact is made at a single point with voltage applied in the same manner, the electric potentials detected in the first electric potential detecting part 131 through the fourth electric potential detecting part 134 are substantially equal in value. Accordingly, a determination as to whether the electric potentials detected in the first electric potential detecting part 131 through the fourth electric potential detecting part 134 are substantially equal may be used to determine whether the number of contact points is one or two.

Further, as described above, the electric potential at Point A is a value obtained by dividing a voltage between the resistance component R₁₂₁ and the resistance component R₁₂₂, and the electric potential at Point B is a value obtained by dividing a voltage between the resistance component R₁₄₁ and the resistance component R₁₄₂. Therefore, it is also possible to detect y coordinate positions at Point A and Point B based on the electric potential detected in the first electric potential detecting part 131 and the electric potential detected in the fourth electric potential detecting part 134.

For example, the correlation between the y coordinate positions at two contact points and the electric potentials detected in the first electric potential detecting part 131 through the fourth electric potential detecting part 134 may be studied in advance, and the y coordinate positions at Point A and Point B may be detected (determined) from the electric potentials detected in the first electric potential detecting part 131 through the fourth electric potential detecting part 134 based on the correlation.

[Case where Two Contact Points are on Straight Line Parallel to X-axis Directions]

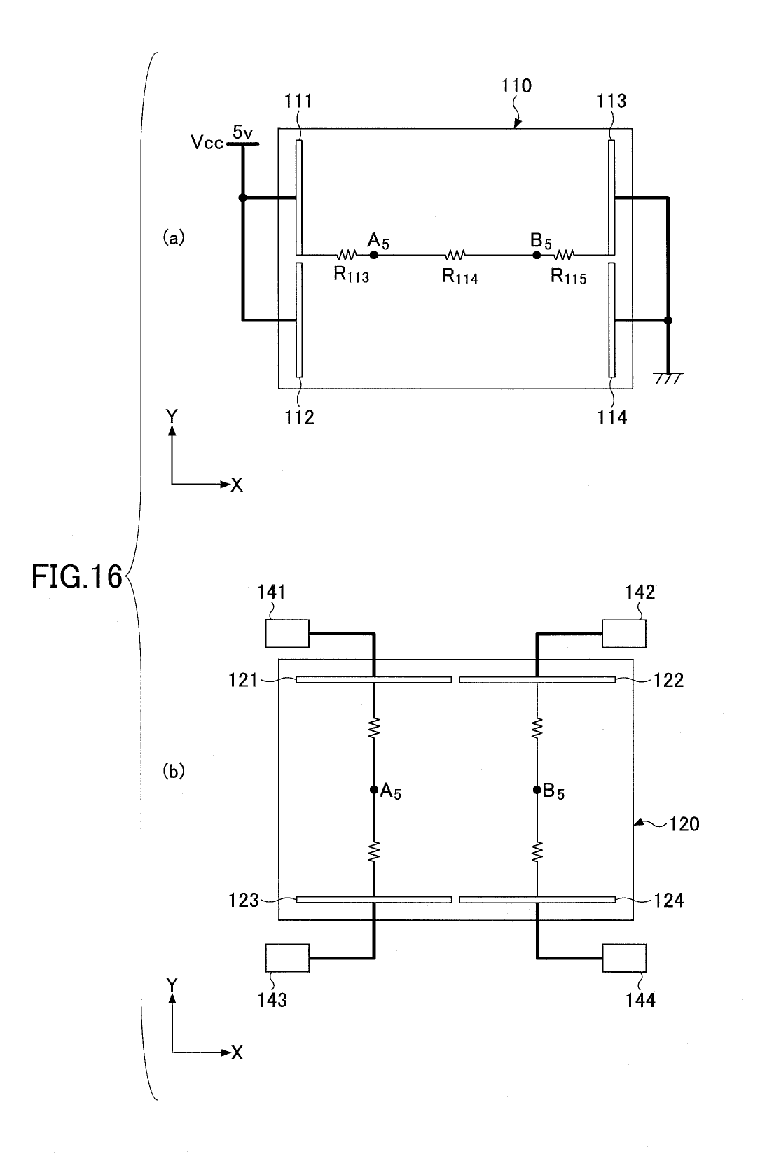

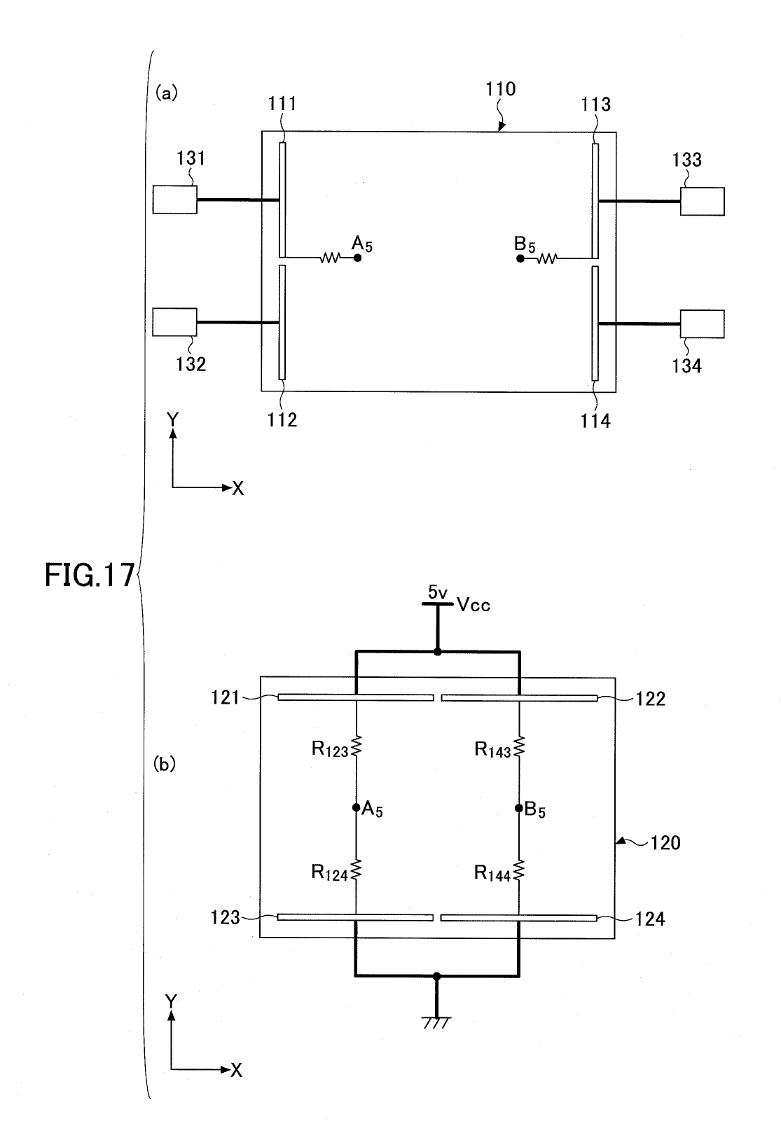

Next, a description is given, with reference to FIG. 16 and FIG. 17, of a case where two contact points are on a straight line parallel to the X-axis directions on the touchscreen panel according to this embodiment.

First, as illustrated in FIG. 16, in the touchscreen panel having the structure illustrated in FIG. 13, the switches 151 and 152 are turned ON and the switches 161 and 162 are turned OFF. As a result, a voltage of 5 V is applied to the first upper electrode 111 and the second upper electrode 112, and the third upper electrode 113 and the fourth upper electrode 114 are grounded, so that an electric potential distribution having a gradient in an X-axis direction is generated in the upper resistive film 110.

It is assumed that in this state, the contact points on the touchscreen panel are Point A₅ and Point B₅ on a straight line parallel to the X-axis directions as illustrated in FIG. 16. In this case, the electric potential at Point A₅ is a value obtained by dividing a voltage between a resistance component R₁₁₃ and resistance components R₁₁₄ and R₁₁₅, that is, 5×(R₁₁₄+R₁₁₅)/(R₁₁₃+R₁₁₄+R₁₁₅) V. Further, the electric potential at Point B₅ is a value obtained by dividing a voltage between the resistance components R₁₁₃ and R₁₁₄ and the resistance component R₁₁₅, that is, 5×R₁₁₅/(R₁₁₃+R₁₁₄+R₁₁₅) V.

These electric potentials are detected via the lower resistive film 120. Since the lower resistive film 120 has a resistance component, the potentials at Point A₅ and Point B₅ strongly affect one or more of the first lower electrode 121 through the fourth lower electrode 124 that are closer to Point A₅ and Point B₅.

That is, in the case illustrated in FIG. 16, the first lower electrode 121 and the third lower electrode 123 are closer than the second lower electrode 122 and the fourth lower electrode 124 at Point A₅, and the second lower electrode 122 and the fourth lower electrode 124 are closer than the first lower electrode 121 and the third lower electrode 123 at Point B₅. In this case, the effect of Point A₅ is dominant in the electric potentials detected at the first lower electrode 121 and the third lower electrode 123, and the effect of Point B₅ is dominant in the electric potentials detected at the second lower electrode 122 and the fourth lower electrode 124.

Thus, different values are detected for the electric potential detected in the fifth electric potential detecting part 141 or the seventh electric potential detecting part 143 via the first lower electrode 121 or the third lower electrode 123 and the electric potential detected in the sixth electric potential detecting part 142 or the eighth electric potential detecting part 144 via the second lower electrode 122 or the fourth lower electrode 124. It is also possible to detect the coordinate positions of x coordinates at Point A₅ and Point B₅ based on these electric potential values.

Next, as illustrated in FIG. 17, in the touchscreen panel having the structure illustrated in FIG. 13, the switches 151 and 152 are turned OFF and the switches 161 and 162 are turned ON. As a result, a voltage of 5 V is applied to the first lower electrode 121 and the second lower electrode 122, and the third lower electrode 123 and the fourth lower electrode 124 are grounded, so that an electric potential distribution having a gradient in a Y-axis direction is generated in the lower resistive film 120.

In this state, if the contact points on the touchscreen panel are Point A₅ and Point B₅ on a straight line parallel to the X-axis directions as illustrated in FIG. 17, the electric potential at Point A₅ is a value obtained by dividing a voltage between a resistance component R₁₂₃ and a resistance component R₁₂₄, that is, 5×R₁₂₄/(R₁₂₃+R₁₂₄) V. Further, the electric potential at Point B₅ is a value obtained by dividing a voltage between a resistance component R₁₄₃ and a resistance component R₁₄₄, that is, 5×R₁₄₄/(R₁₄₃+R₁₄₄) V.

Here, Point A₅ and Point B₅ are contact points on a straight line parallel to the X-axis directions. Therefore, the resistance components R₁₂₃ and R₁₄₃ are equal in resistance value (R₁₂₃=R₁₄₃) and the resistance components R₁₂₄ and R₁₄₄ are equal in resistance value (R₁₂₄=R₁₄₄), so that the electric potential at Point A₅ and the electric potential at Point B₅ are equal. Accordingly, the electric potentials detected in the first electric potential detecting part 131 through the fourth electric potential detecting part 134 via the first upper electrode 111 through the fourth upper electrode 114, respectively, are substantially equal. It is also possible to detect the coordinate positions of y coordinates at Point A₅ and Point B₅ based on these potential values.

Thus, in the case of applying voltage so that an electric potential distribution is generated in the X-axis directions as illustrated in FIG. 16, it is possible to detect (determine) that the contact points on the touchscreen panel according to this embodiment are two Points A₅ and B₅ in response to the electric potential detected in the fifth electric potential detecting part 141 via the first lower electrode 121 and the electric potential detected in the seventh electric potential detecting part 143 via the third lower electrode 123 being different in value from the electric potential detected in the sixth electric potential detecting part 142 via the second lower electrode 122 and the electric potential detected in the eighth electric potential detecting part 144 via the fourth lower electrode 124. It may also be determined that the contact points on the touchscreen panel according to this embodiment are two Points A₅ and B₅ in response to determining that at least one of the electric potentials detected in the fifth electric potential detecting part 141 through the eighth electric potential detecting part 144 via the first lower electrode 121 through the fourth lower electrode 124, respectively, is different in value from another one of the detected electric potentials.

Further, in the case of applying voltage so that an electric potential distribution is generated in the Y-axis directions as illustrated in FIG. 17, it is possible to determine that contact points (Point A₅ and Point B₅) are on a straight line parallel to the X-axis directions on the touchscreen panel according to this embodiment in response to detecting electric potentials of substantially the same value in the first electric potential detecting part 131 through the fourth electric potential detecting part 134 via the first upper electrode 111 through the fourth upper electrode 114, respectively.

[Case where Two Contact Points are on Straight Line Parallel to Y-axis Directions]

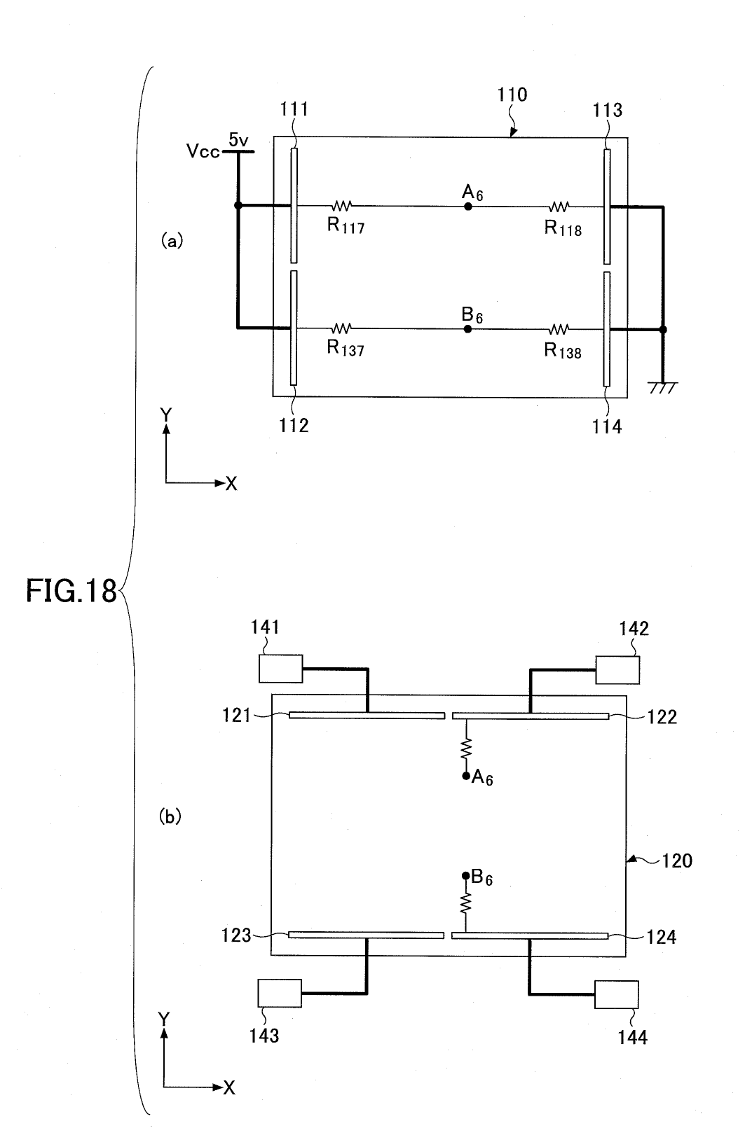

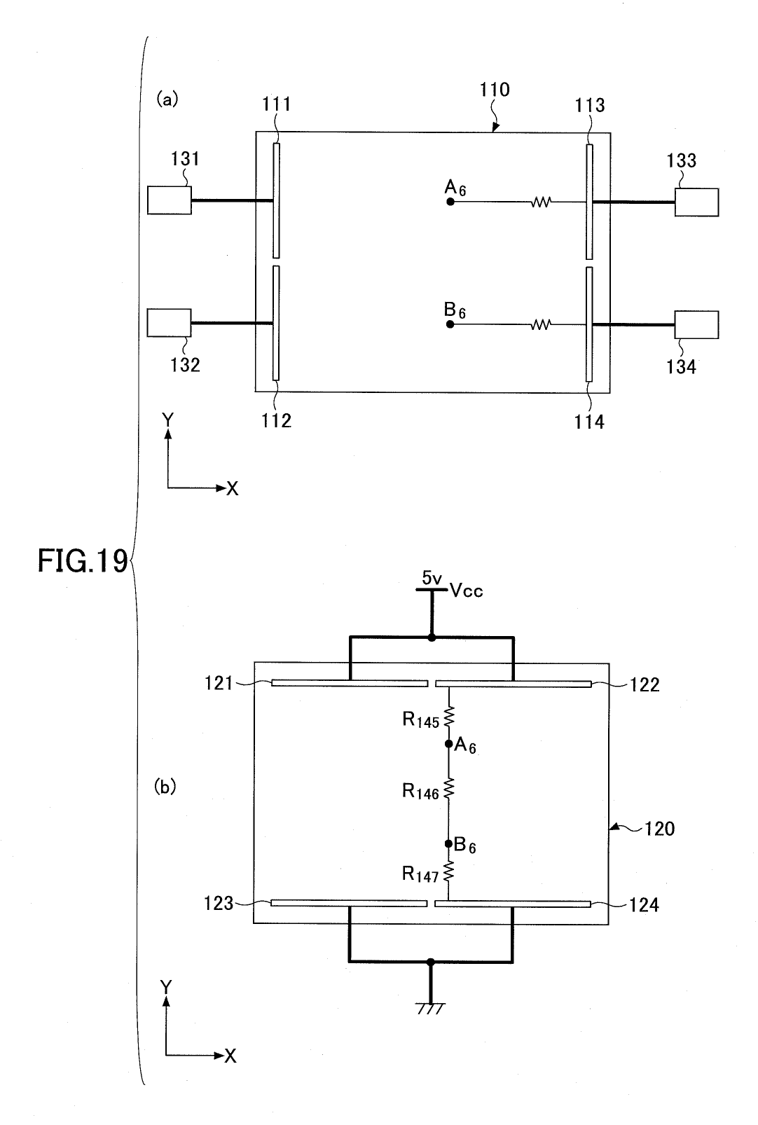

Next, a description is given, with reference to FIG. 18 and FIG. 19, of a case where two contact points are on a straight line parallel to the Y-axis directions on the touchscreen panel according to this embodiment.

First, as illustrated in FIG. 18, in the touchscreen panel having the structure illustrated in FIG. 13, the switches 151 and 152 are turned ON and the switches 161 and 162 are turned OFF. As a result, a voltage of 5 V is applied to the first upper electrode 111 and the second upper electrode 112, and the third upper electrode 113 and the fourth upper electrode 114 are grounded, so that an electric potential distribution having a gradient in an X-axis direction is generated in the upper resistive film 110.

In this state, if the contact points on the touchscreen panel are Point A₆ and Point B₆ on a straight line parallel to the Y-axis directions as illustrated in FIG. 18, the electric potential at Point A₆ is a value obtained by dividing a voltage between a resistance component R₁₁₇ and a resistance component R₁₁₈, that is, 5×R₁₁₈/(R₁₁₇+R₁₁₈) V. Further, the electric potential at Point B₆ is a value obtained by dividing a voltage between a resistance component R₁₃₇ and a resistance component R₁₃₈, that is, 5×R₁₃₈/(R₁₃₇+R₁₃₈) V.

Here, Point A₆ and Point B₆ are contact points on a straight line parallel to the Y-axis directions. Therefore, the resistance components R₁₁₇ and R₁₃₇ are equal in resistance value (R₁₁₇=R₁₃₇) and the resistance components R₁₁₈ and R₁₃₈ are equal in resistance value (R₁₁₈=R₁₃₈), so that the electric potential at Point A₆ and the electric potential at Point B₆ are equal. Accordingly, the electric potentials detected in the fifth electric potential detecting part 141 through the eighth electric potential detecting part 144 via the first lower electrode 121 through the fourth lower electrode 124, respectively, are substantially equal. It is also possible to detect the coordinate positions of x coordinates at Point A₆ and Point B₆ based on these potential values.

Next, as illustrated in FIG. 19, in the touchscreen panel having the structure illustrated in FIG. 13, the switches 151 and 152 are turned OFF and the switches 161 and 162 are turned ON. As a result, a voltage of 5 V is applied to the first lower electrode 121 and the second lower electrode 122, and the third lower electrode 123 and the fourth lower electrode 124 are grounded, so that an electric potential distribution having a gradient in a Y-axis direction is generated in the lower resistive film 120.

It is assumed that in this state, the contact points on the touchscreen panel are Point A₆ and Point B₆ on a straight line parallel to the Y-axis directions as illustrated in FIG. 19. In this case, the electric potential at Point A₆ is a value obtained by dividing a voltage between a resistance component R₁₄₅ and resistance components R₁₄₆ and R₁₄₇, that is, 5×(R₁₄₆+R₁₄₇)/(R₁₄₅+R₁₄₆+R₁₄₇) V. Further, the electric potential at Point B₆ is a value obtained by dividing a voltage between the resistance components R₁₄₅ and R₁₄₆ and the resistance component R₁₄₇, that is, 5×R₁₄₇/(R₁₄₅+R₁₄₆+R₁₄₇) V.

These electric potentials are detected via the upper resistive film 110. Since the upper resistive film 110 has a resistance component, the potentials at Point A₆ and Point B₆ strongly affect one or more of the first upper electrode 111 through the fourth upper electrode 114 that are closer to Point A₆ and Point B₆.

For example, in the case illustrated in FIG. 19, the first upper electrode 111 and the third upper electrode 113 are closer than the second upper electrode 112 and the fourth upper electrode 114 at Point A₆, and the second upper electrode 112 and the fourth upper electrode 114 are closer than the first upper electrode 111 and the third upper electrode 113 at Point B₆. In this case, the effect of Point A₆ is dominant in the electric potentials detected at the first upper electrode 111 and the third upper electrode 113, and the effect of Point B₆ is dominant in the electric potentials detected at the second upper electrode 112 and the fourth upper electrode 114.

Accordingly, the electric potentials detected in the first electric potential detecting part 131 and the third electric potential detecting part 133 via the first upper electrode 111 and the third upper electrode 113, respectively, are different in value from the electric potentials detected in the second electric potential detecting part 132 and the fourth electric potential detecting part 134 via the second upper electrode 112 and the fourth upper electrode 114, respectively. It is also possible to detect the coordinate positions of y coordinates at Point A₆ and Point B₆ based on these potential values.

Thus, in the case of applying voltage so that an electric potential distribution is generated in the Y-axis directions as illustrated in FIG. 19, it is possible to detect (determine) that the contact points on the touchscreen panel according to this embodiment are two Points A₆ and B₆ in response to the electric potential detected in the first electric potential detecting part 131 via the first upper electrode 111 and the electric potential detected in the third electric potential detecting part 133 via the third upper electrode 113 being different in value from the electric potential detected in the second electric potential detecting part 132 via the second upper electrode 112 and the electric potential detected in the fourth electric potential detecting part 134 via the fourth upper electrode 114. It may also be determined that the contact points on the touchscreen panel according to this embodiment are two Points A₆ and B₆ in response to determining that at least one of the electric potentials detected in the first electric potential detecting part 131 through the fourth electric potential detecting part 134 via the first upper electrode 111 through the fourth upper electrode 114, respectively, is different in value from another one of the detected electric potentials.

Further, in the case of applying voltage so that an electric potential distribution is generated in the X-axis directions as illustrated in FIG. 18, it is possible to determine that contact points (Point A₆ and Point B₆) are on a straight line parallel to the Y-axis directions on the touchscreen panel according to this embodiment in response to detecting electric potentials of substantially the same value in the fifth electric potential detecting part 141 through the eighth electric potential detecting part 144 via the first lower electrode 121 through the fourth lower electrode 124, respectively.

In the case other than those described above, that is, in the case where electric potentials of substantially the same value are detected in the fifth electric potential detecting part 141 through the eighth electric potential detecting part 144 via the first lower electrode 121 through the fourth lower electrode 124, respectively, in the case of applying voltage so that an electric potential distribution is generated in the X-axis directions and electric potentials of substantially the same value are detected in the first electric potential detecting part 131 through the fourth electric potential detecting part 134 via the first upper electrode 111 through the fourth upper electrode 114, respectively, in the case of applying voltage so that an electric potential distribution is generated in the Y-axis directions, it is determined that the number of contact points on the touchscreen panel is one.

Thus, according to the touchscreen panel of this embodiment, it is possible to detect contact positions at two points also in the case where a line segment connecting two contact points is parallel to the X-axis directions or parallel to the Y-axis directions.

The second embodiment may be the same as the first embodiment in other respects than those described above.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that various changes, substitutions, and alterations could be made hereto without departing from the spirit and scope of the invention.

What is claimed is:

1. A touchscreen panel, comprising:
an upper resistive film including a first upper electrode and a second upper electrode provided at a first end and a second end, respectively, in a first direction;
a lower resistive film including a first lower electrode and a second lower electrode provided at a first end and a second end, respectively, in a second direction perpendicular to the first direction;
a first electric potential detecting part connected to the first upper electrode;
a second electric potential detecting part connected to the second upper electrode;
a third electric potential detecting part connected to the first lower electrode; and
a fourth electric potential detecting part connected to the second lower electrode.

2. The touchscreen panel as claimed in claim 1, further comprising:
a first switch for controlling whether to provide the first upper electrode with a first electric potential, the first switch being connected to the first upper electrode;
a second switch for controlling whether to provide the second upper electrode with a second electric potential different from the first electric potential, the second switch being connected to the second upper electrode;
a third switch for controlling whether to provide the first lower electrode with the first electric potential, the third switch being connected to the first lower electrode; and
a fourth switch for controlling whether to provide the second lower electrode with the second electric potential, the fourth switch being connected to the second lower electrode.

3. The touchscreen panel as claimed in claim 1, further comprising:
a control part connected to the first electric potential detecting part, the second electric potential detecting part, the third electric potential detecting part, and the fourth electric potential detecting part,
the control part being configured to determine a number of contact points on the touchscreen panel is one in response to an electric potential detected in the first electric potential detecting part and an electric potential detected in the second electric potential detecting part being equal with an electric potential distribution generated in the second direction in the lower resistive film and an electric potential detected in the third electric potential detecting part and an electric potential detected in the fourth electric potential detecting part being equal with an electric potential distribution generated in the first direction in the upper resistive film.

4. The touchscreen panel as claimed in claim 1, further comprising:
a control part connected to the first electric potential detecting part, the second electric potential detecting part, the third electric potential detecting part, and the fourth electric potential detecting part,
the control part being configured to determine a number of contact points is two or more in response to an electric potential detected in the first electric potential detecting part and an electric potential detected in the second electric potential detecting part being different with an electric potential distribution generated in the second direction in the lower resistive film or an electric potential detected in the third electric potential detecting part and an electric potential detected in the fourth electric potential detecting part being different with an electric potential distribution generated in the first direction in the upper resistive film.

5. The touchscreen panel as claimed in claim 4, wherein the control part is configured to detect a direction of movement of each of the two contact points based on changes in the electric potentials in the first electric potential detecting part, the second electric potential detecting part, the third electric potential detecting part, and the fourth electric potential detecting part.

6. A touchscreen panel, comprising:
an upper resistive film including a first upper electrode and a second upper electrode provided at a first end and a second end, respectively, in a first direction, the first upper electrode and the second upper electrode each being divided into a plurality of portions;
a lower resistive film including a first lower electrode and a second lower electrode provided at a first end and a second end, respectively, in a second direction perpendicular to the first direction, the first lower electrode and the second lower electrode each being divided into a plurality of portions;
a plurality of first electric potential detecting parts connected to the portions of the first upper electrode on a one-to-one basis;
a plurality of second electric potential detecting parts connected to the portions of the second upper electrode on a one-to-one basis;
a plurality of third electric potential detecting parts connected to the portions of the first lower electrode on a one-to-one basis; and
a plurality of fourth electric potential detecting parts connected to the portions of the second lower electrode on a one-to-one basis.

7. The touchscreen panel as claimed in claim 6, further comprising:
a first switch for controlling whether to provide the first upper electrode with a first electric potential, the first switch being connected to the first upper electrode;
a second switch for controlling whether to provide the second upper electrode with a second electric potential different from the first electric potential, the second switch being connected to the second upper electrode;
a third switch for controlling whether to provide the first lower electrode with the first electric potential, the third switch being connected to the first lower electrode; and
a fourth switch for controlling whether to provide the second lower electrode with the second electric potential, the fourth switch being connected to the second lower electrode.

8. The touchscreen panel as claimed in claim 6, further comprising:
a control part connected to the first electric potential detecting parts, the second electric potential detecting parts, the third electric potential detecting parts, and the fourth electric potential detecting parts,
the control part being configured to determine a number of contact points on the touchscreen panel is one in response to all of electric potentials detected in the first electric potential detecting parts and the second electric potential detecting parts being equal with an electric potential distribution generated in the second direction in the lower resistive film and all of electric potentials detected in the third electric potential detecting parts and the fourth electric potential detecting parts being equal with an electric potential distribution generated in the first direction in the upper resistive film.

9. The touchscreen panel as claimed in claim 6, further comprising:
a control part connected to the first electric potential detecting parts, the second electric potential detecting parts, the third electric potential detecting parts, and the fourth electric potential detecting parts,
the control part being configured to determine a number of contact points is two or more in response to at least one of electric potentials detected in the first electric potential detecting parts and the second electric potential detecting parts being different from another one of the electric potentials detected in the first electric potential detecting parts and the second electric potential detecting parts with an electric potential distribution generated in the second direction in the lower resistive film or at least one of electric potentials detected in the third electric potential detecting parts and the fourth electric potential detecting parts being different from another one of the electric potentials detected in the third electric potential detecting parts and the fourth electric potential detecting parts with an electric potential distribution generated in the first direction in the upper resistive film.
